(19) United States
(12) Patent Application Publication
(10) Pub. No.: US 2005/0233251 A1
(43) Pub. Date: Oct. 20, 2005

(54) Lithographic printing plate precursor and lithographic printing method

(75) Inventors: Ryuki Kakino, Haibara-gun (JP); Kazuto Kunita, Haibara-gun (JP); Yasuhito Oshima, Haibara-gun (JP)

Correspondence Address: BIRCH STEWART KOLASCH & BIRCH, PO BOX 747, FALLS CHURCH, VA, 22040-0747, US

(73) Assignee: Fuji Photo Film Co., Ltd.

(21) Appl. No.: 11/106,502

(22) Filed: Apr. 15, 2005

(30) Foreign Application Priority Data
Apr. 20, 2004 (JP) P. 2004-123805

(51) Int. Cl. G03F 7/00

(52) U.S. Cl. 430/300

(57) ABSTRACT

A lithographic printing plate precursor comprises: a support; and a photosensitive-thermosensitive layer that allows image recording by exposure to an infrared laser light, wherein the photosensitive-thermosensitive layer comprises (1) an infrared absorbent and (2) a compound which undergoes color change upon oxidation or reduction.

### BACKGROUND OF THE INVENTION

1. Field of the Invention

The present invention relates to a lithographic printing plate precursor and a lithographic printing method using the same. More specifically, the invention relates to a lithographic printing plate precursor which has a hydrophilic support and a photosensitive-thermosensitive layer comprising microcapsules, and which enables printing without going through the development step after exposure to light, a method of platemaking using said lithographic printing plate precursor, and a lithographic printing method in which said lithographic printing plate precursor is used in printing.

2. Description of the Related Art

In general, a lithographic printing plate consists of an oleophilic image area which is receptive to ink and a hydrophilic non-image area which is receptive to fountain solution in the process of printing. Lithographic printing is a method of printing which utilizes the nature of water and oily ink repelling each other, wherein printing is carried out by employing the oleophilic image area as an ink-receiving area and the hydrophilic non-image area as a fountain solution-receiving area (a non-ink-receiving area) in a lithographic printing plate and causing a discrepancy in the ink depositability at the surface of the lithographic printing plate, so as to result in ink depositing on the image area only and subsequently transferring the ink onto a printing substrate such as paper.

In constructing such a lithographic printing plate, a lithographic printing plate precursor having an oleophilic photosensitive resin layer (image-recording layer) formed on a hydrophilic support (a PS plate) has been widely used hitherto. A lithographic printing plate is usually prepared by exposing a lithographic printing plate precursor to light through a printing master such as a lith film and then removing the image-recording layer in the non-image area by dissolution with an alkaline developing solution or an organic solvent, while leaving an image-recording layer in the image area, thereby exposing the surface of the hydrophilic support.

The existing platemaking process for lithographic printing plate precursor necessitates a step of removing the non-image area after light exposure by dissolution with a developing solution which is compatible with the image-recording layer, or the like. However, elimination or simplification of such additional wet treatment is currently listed as a problem to be solved. Particularly, disposal of the waste solutions discharged from the wet treatment has recently attracted much industrial attention in view of the consideration for global environment. Thus, there is an increasing demand for a solution to the foregoing problem.

In this regard, there has been proposed, as a non-treatment (non-development) type not requiring wet treatment, a lithographic printing plate precursor that comprises a photosensitive-thermosensitive layer in which the affinity to the fountain solution or the ink changes in accordance with exposure to light at the surface of the layer, thereby enabling printing without the removal of the photosensitive-thermosensitive layer.

Further, as one of simple and convenient platemaking methods, there has been proposed a method so-called as on-board development method, in which an image-recording layer capable of the removal of the non-image area in a lithographic printing plate precursor in the course of the common printing process, is used to remove the non-image area on the printing press after exposure to light, thereby resulting in a lithographic printing plate.

Specific examples of the on-board development method may include a method of using a lithographic printing plate precursor having an image-recording layer that can be dissolved or dispersed in a fountain solution, an ink solvent or an emulsion of a fountain solution and ink; a method of mechanically removing an image-recording layer by means of contact with an impression cylinder or a blanket cylinder of a printing press; or a method of attenuating the cohesion of an image-recording layer or the adhesion between an image recording layer and a support by penetration of a fountain solution, an ink solvent or the like and then mechanically removing the image-recording layer by means of contact with an impression cylinder or a blanket cylinder.

In addition, unless specified otherwise, the term “development treatment process” as used in the invention means a step of removing an area unexposed to infrared laser light in the image-recording layer of a lithographic printing plate precursor by contacting the image-recording layer with a liquid (usually an alkaline developing solution) by using an apparatus other than a printing press (usually an automatic developing machine), in order to expose the surface of the hydrophilic support. On the other hand, the term “on-board development” means a method and its process of removing an area unexposed to infrared laser light in the image-recording layer of a lithographic printing plate precursor by contacting the image-recording layer with a liquid (usually a printing ink and/or a fountain solution) by using a printing press, in order to expose the surface of the hydrophilic support.

However, in the case of using the image-recording layer in the related-art image-recording method utilizing the ultraviolet ray or visible light, since the image-recording layer is not fixed even after exposure to light, it has been required to employ a troublesome method of, for example, storing the lithographic printing plate precursor after light exposure in a completely light-shielded state or under constant temperature conditions until the point of time to mount the lithographic printing plate precursor on the printing press.

Meanwhile, with the recent spread of digitalization technology of electronically processing, storing and outputting image information by computer, various new image outputting systems coping with such digitalization technology have been put to practical use. In this connection, attention has been given on the computer-to-plate technology of directly preparing a lithographic printing plate without the use of a lith film, by loading digitalized image information on a highly converging radiation ray such as laser light and scan-exposing a lithographic printing plate precursor with the same light. Accordingly, it is one of important technical subjects to obtain a lithographic printing plate precursor that is adaptable to such technology as described above.

As discussed above, a demand for simplification, introduction of dry processes, and elimination of treatment with respect to the platemaking operation is significantly increasing in recent years in the aspects of consideration on the global environment as well as adaptation to digitalization.

Recently, high output lasers such as semiconductor lasers and YAG lasers emitting infrared rays of 760 nm to 1200 nm in wavelength have become available inexpensively. Thus, it is highly expected that these high output lasers are utilized as an image recording means in a method of manufacturing a lithographic printing plate by scan-exposure, which can be easily incorporated into the digitalization technology.

In the the related-art platemaking method, a photosensitive lithographic printing plate precursor is exposed to an image pattern at a low to medium illumination intensity, and the property changes in the image pattern induced from a photochemical reaction in the image-recording layer is utilized in the implementation of image recording. On the contrary, in a method of using the above-mentioned high output lasers, an area to be exposed is radiated with a large quantity of light energy in an extremely short period of time to convert the light energy efficiently into heat energy, this heat energy induces thermal changes such as chemical changes, phase changes, or morphological or structural changes in the image recording layer, and these changes are utilized in the implementation of image recording. Therefore, image information is input by means of light energy such as laser light, whereas image recording is achieved by means of a combination of light energy and reactions induced by heat energy. Typically, such a recording system making use of the heat generated by exposure to a high power density light is referred to as “heat mode recording,” and the conversion of light energy into heat energy is referred to as “photothermal conversion.” In this invention, such image-recording layer as described above is referred to as the photosensitive-thermosensitive layer.

A great advantage of the platemaking method of employing the heat mode recording is that the image-recording layer would not be sensitized under an ordinary level of illumination such as room light, and that fixation of an image recorded by exposure to a light of high intensity of illumination is not essential. That is, a lithographic printing plate precursor used in the heat mode recording is free from any fear of the precursor being sensitized by room light prior to the exposure proper, and fixation of image is not essential after light exposure. Therefore, for example, when a platemaking process is carried out in the on-board development mode, in which process an image recording layer which becomes insolubilized or solubilized by exposure using high output lasers is used to produce a lithographic printing plate having the light-exposed image-recording layer as the image pattern, it is possible to obtain a printing system which would not have an effect on the image even if it were exposed to the ambient room light after the exposure proper. Thus, it is expected to be possible with the use of the heat mode recording, to obtain a lithographic printing plate precursor which may be very appropriately used in the on-board development.

In this regard, Japanese Patent No. 2938397, for example, discloses a lithographic printing plate precursor having provided on a hydrophilic support, an image-formation layer in which hydrophobic thermoplastic polymer particles are dispersed in a hydrophilic binder. Japanese Patent No. 2938397 describes that it is possible to expose said lithographic printing plate precursor to an infrared laser and form an image by means of coalescence of the hydrophobic thermoplastic polymer particles by heat, and then to attach the plate precursor on the cylinder of the printing press and to develop on-board using a fountain solution and/or an ink.

However, it was discovered regarding the foregoing method of forming an image by coalescence of microparticles resulting from simple thermal fusion, that although the method exhibits good ability for the on-board development, it results in weak image intensity and insufficient resistance to printing.

For this reason, it has been proposed to improve the resistance to printing using a polymerization reaction. For instance, JP-A No. 2001-277740 describes a lithographic printing plate precursor having an image-recording layer (thermosensitive layer) containing microcapsules which comprise a polymeric compound, on a hydrophilic support. Furthermore, JP-A No. 2002-287334 describes a lithographic printing plate precursor having a support and an image-recording layer (photosensitive layer) containing an infrared absorbent, a radical polymerization initiator and a polymeric compound constructed thereon.

In general, as a step preceding the mounting of a printing plate to the printing press, an operation of inspection and identification of the image on the printing plate is carried out in the aspects of whether image recording is done on the printing plate as intended, how many ink colors can be used for the printing plate, or the like. For the related-art lithographic printing plate precursor necessitating the process of development, it becomes generally easy to confirm the image after platemaking (after development) and before printing (before mounting the printing plate on the printing press), by having the image-recording layer colored.

However, for a lithographic printing plate precursor of the on-board development type or the non-treatment (non-development) type, which does not require the process of development prior to printing, image does not exist on the printing plate and identification of the printing plate cannot be carried out in the step of mounting the printing plate on the printing press. Consequently, often there occur mistakes in the operation. Particularly, it is considered important in the printing process for multicolor printing, the ability to judge whether the register mark that serves as an index to estimate the position appears clearly. The object of the invention is to provide a solution to such problem.

### SUMMARY OF THE INVENTION

That is to say, the object of the invention is to provide a lithographic printing plate precursor of the on-board development type or the non-treatment (non-development) type, which allows burning of an image having high visibility that facilitates identification of the plate after the step of heating or irradiation with an infrared laser to an image form. Another object of the invention is to provide a platemaking method for such lithographic printing plate precursor of the on-board development type, and a lithographic printing method using this lithographic printing plate precursor.

The inventors diligently investigated in order to achieve the above-described objects and found that it is possible to allow direct color change and to obtain an image burned to have high visibility, by using an infrared absorbent and a compound which undergoes color change upon oxidation or reduction, thereby completing the invention.

Thus, the invention comprises the following:
1. A lithographic printing plate precursor comprising: a support; and a photosensitive-thermosensitive layer that allows image recording by exposure to an infrared laser light, wherein the photosensitive-thermosensitive layer comprises (1) an infrared absorbent and (2) a compound which undergoes color change upon oxidation or reduction.

2. The lithographic printing plate precursor as described in the above item 1, wherein the infrared absorbent (1) is at least one selected from cyanine colorants, melocyanine colorants and oxonol colorants, and the compound (2) which undergoes color change upon oxidation is at least one selected from leuco triarylmethane compounds, leuco diarylmethane compounds, leuco xanthene compounds, leuco thioxanthene compounds and arylamine compounds.

3. The lithographic printing plate precursor as described in the above item 1, wherein the infrared absorbent (1) is at least one selected from cyanine colorants, pyrylium colorants and thiopyrylium colorants, and the compound (2) which undergoes color change upon reduction is at least one selected from diarylmethane colorants, triarylmethane colorants, thiazine colorants, xanthene colorants and azomethine colorants.

4. The lithographic printing plate precursor as described in any one of the above items 1 to 3, wherein the photosensitive-thermosensitive layer further comprises (3) a radical-polymerizable compound and a radical polymerization initiator.

5. The lithographic printing plate precursor as described in the above item 4, wherein at least one of said components (1) to (3) is encapsulated in microcapsules.

6. A platemaking method for a lithographic printing plate precursor, comprising: mounting the lithographic printing plate precursor as described in any one of the above items 1 to 5, on a printing press; imagewise exposing the lithographic printing plate precursor with an infrared laser; and supplying printing ink and fountain solution onto the lithographic printing plate precursor to remove an infrared laser light-unexposed area of the photosensitive-thermosensitive layer.

7. The platemaking method for a lithographic printing plate precursor as described in item 6, wherein the mounting is performed before the imagewise exposing.

8. The platemaking method for a lithographic printing plate precursor as described in item 6, wherein the mounting is performed after the imagewise exposing.

9. A lithographic printing method comprising: mounting the lithographic printing plate precursor as described in any one of the above items 1 to 5, on a printing press; imagewise exposing the lithographic printing plate precursor with an infrared laser; supplying printing ink and fountain solution onto the lithographic printing plate precursor to remove an infrared laser light-unexposed area of the photosensitive-thermosensitive layer; and printing.

10. The lithographic printing method as described in item 9, wherein the mounting is performed before the imagewise exposing.

11. The lithographic printing method as described in item 9, wherein the mounting is performed after the imagewise exposing.

It is noted that the mounting of the lithographic printing plate precursor to the printing press may be performed either before or after the image imagewise exposing of the lithographic printing plate precursor.

Although the operating mechanism of the invention has not been clarified, it is inferred that as compared with the method well-known hitherto in the art of generating an acid, a base or a radical from an acid-, base- or radical-generating agent by light exposure and thereby changing the color of a compound which undergoes color change by interacting with the generated acid, base or radical, the method of the invention involves a direct reaction between an infrared absorbent excited by exposure to light and a compound undergoing color change, without requiring an acid-, base- or radical-generating agent, thus allowing a high sensitivity for the formation of burned images and thereby allowing the formation of images with excellent visibility.

### DETAILED DESCRIPTION OF THE INVENTION

The present invention is characterized in that a photosensitive-thermosensitive layer which allows image recording by exposure to an infrared laser light is provided on a support, and the photosensitive-thermosensitive layer comprises (1) an infrared absorbent and (2) a compound which undergoes color change upon oxidation or reduction, in order to yield burned images of high visibility on a lithographic printing plate precursor (a lithographic printing plate precursor of the on-board development type or of the non-treatment (non-development) type) which enables printing by mounting the precursor on a printing press after image recording without going through the development step, or by recording an image on the precursor after mounting on a printing press.

For the lithographic printing plate precursor of the invention which enables printing by mounting the precursor on a printing press after image recording without going through the development step, or by recording an image on the precursor after mounting on a printing press, mention may be made of (1) the lithographic printing plate precursor of the on-board development type and (2) the lithographic printing plate precursor of the non-treatment (non-development) type as described below.

(1) Lithographic Printing Plate Precursor of the On-Board Development Type:

A lithographic printing plate precursor having a photosensitive-thermosensitive layer whose solubility or dispersibility with respect to fountain solution and/or ink changes by light exposure, or whose adhesiveness to an adjacent layer having a different affinity to fountain solution or ink changes by light exposure, which allows developing an image after light exposure by supplying of a fountain solution and/or an ink on the surface of the plate on a printing press.

(2) Lithographic Printing Plate Precursor of the Non-Treatment (Non-Development) Type:

A lithographic printing plate precursor having a photosensitive-thermosensitive layer whose affinity to fountain solution or ink changes on the surface by light exposure, which enables printing without removal of the photosensitive-thermosensitive layer after light exposure of the image.

For the lithographic printing plate precursor of the invention which allows printing by mounting the precursor on a printing press without going through the development step after image recording, or by recording an image on the precursor after mounting on a printing press, there is no particular limitation as long as it is the lithographic printing plate precursor of the above (1) or (2). However, as described below, since a lithographic printing plate precursor of the on-board development type does not necessarily involve a crosslinked structure in the photosensitive-thermosensitive layer, the compound which undergoes color change by light exposure in the photosensitive-thermosensitive layer has higher mobility, and thus it is likely that the reactivity of the color change be improved. Therefore, a lithographic printing plate precursor of the on-board development type is more preferred to that of the non-treatment (non-development) type which involves a crosslinked structure in the photosensitive-thermosensitive layer.

Specifically, mention may be made of those plate materials described in Japanese Patent No. 2938397, JP-A Nos. 2001-277740, 2001-277742, 2002-287334, 2001-96936, 2001-96938, 2001-180141 and 2001-162960, the pamphlets of WO 00/16987 and WO 01/39985, EP-A Nos. 990517 and 1225041, U.S. Pat. No. 6,465,152, JP-A No. 6-317899, the pamphlet of WO 96/35143, EP-A No. 652483, JP-A Nos. 10-10737 and 11-309952, U.S. Pat. Nos. 6,017,677 and 6,413,694, and the like.

Hereinafter, a detailed explanation on the constituents of the lithographic printing plate precursor of the invention and the printing method of using the lithographic printing plate precursor will be offered.

[Photosensitive-Thermosensitive Layer]

The photosensitive-thermosensitive layer of the invention is characterized in containing (1) an infrared absorbent and (2) a compound which undergoes color change upon oxidation or reduction.

This infrared absorbent is excited with an infrared laser light to cause direct color change in the compound which undergoes color change upon oxidation or reduction, and burned images of high visibility can be obtained thereby.

<Compound which Undergoes Color Change upon Oxidation or Reduction>

1. Compound which Undergoes Color Change upon Oxidation

The compound which undergoes color change upon oxidation according to the invention may include, for example, leuco triarylmethane compounds, leuco diarylmethane compounds, leuco xanthene compounds, leuco thioxanthene compounds, arylamine compounds and the like. Specific examples of these compounds are as follows:

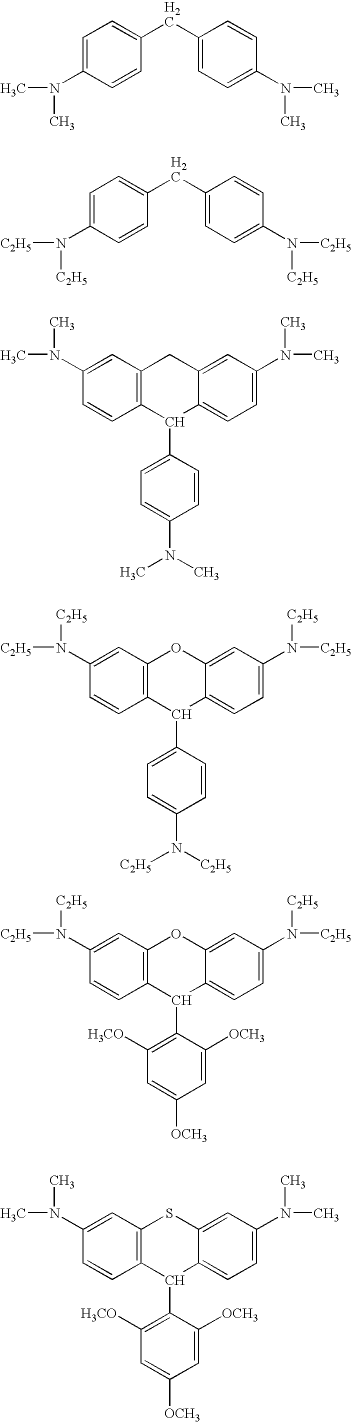

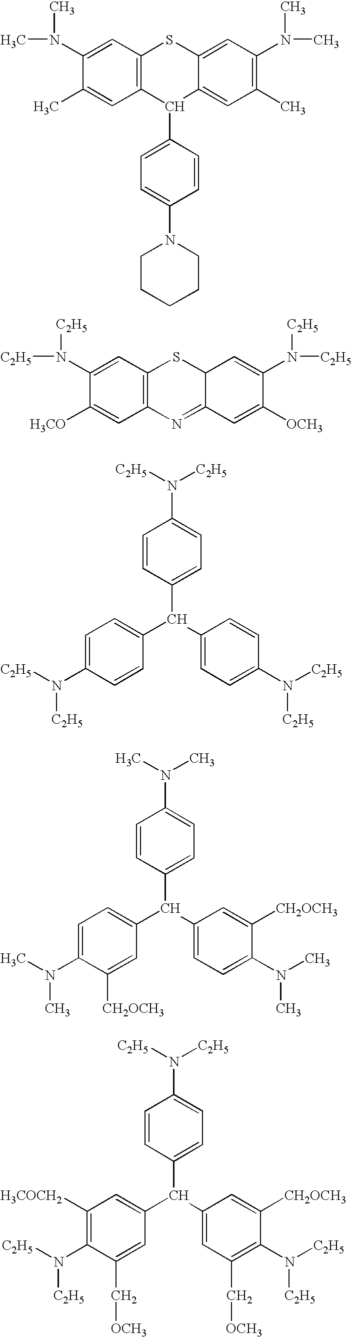

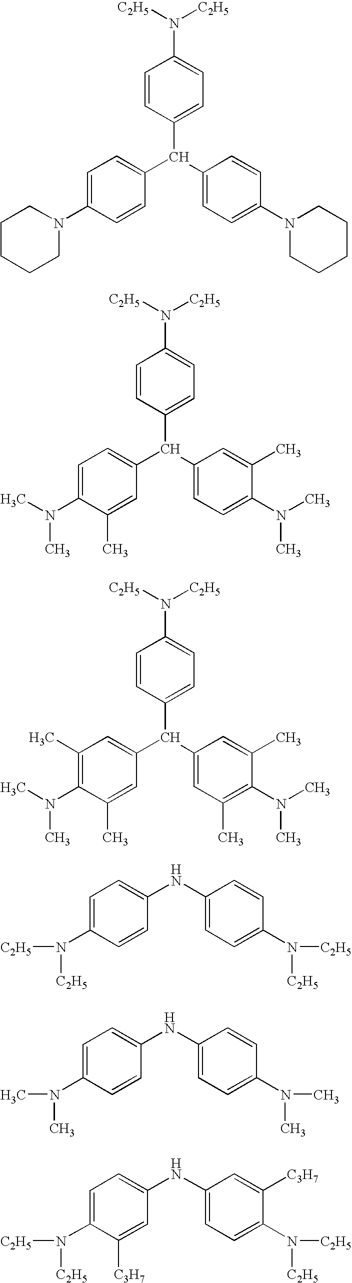

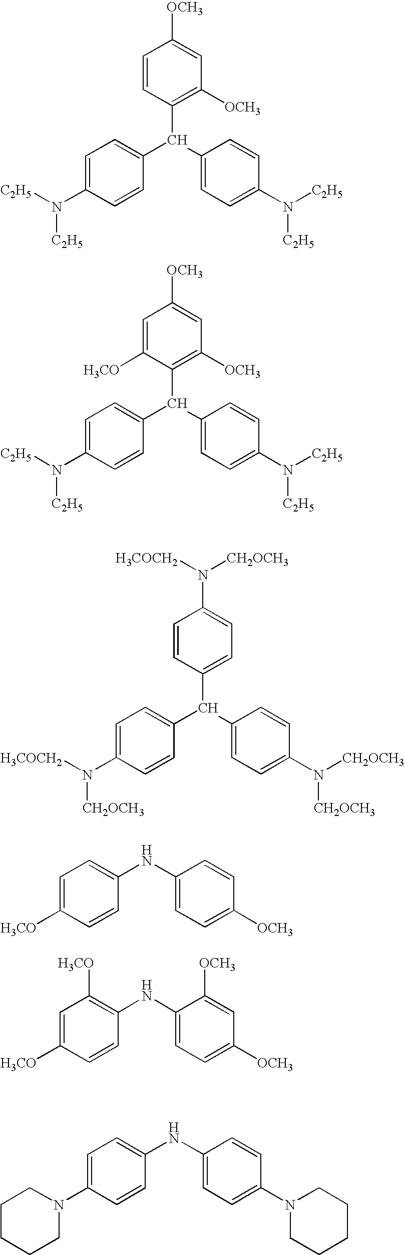

Among the above-mentioned compounds, leuco triarylmethane compounds, leuco diarylmethane compounds and arylamine compounds are most preferred, and particularly preferred are leuco triarylmethane compounds and diarylamine compounds.

2. Compound which Undergoes Color Change upon Reduction

As the compound which undergoes color change upon reduction according to the invention, for example, various colorants such as diarylmethane-based, triarylmethane-based, thiazine-based, xanthene-based and azomethine-based colorants and the like are effectively used. Specific examples of these colorants are as follows:

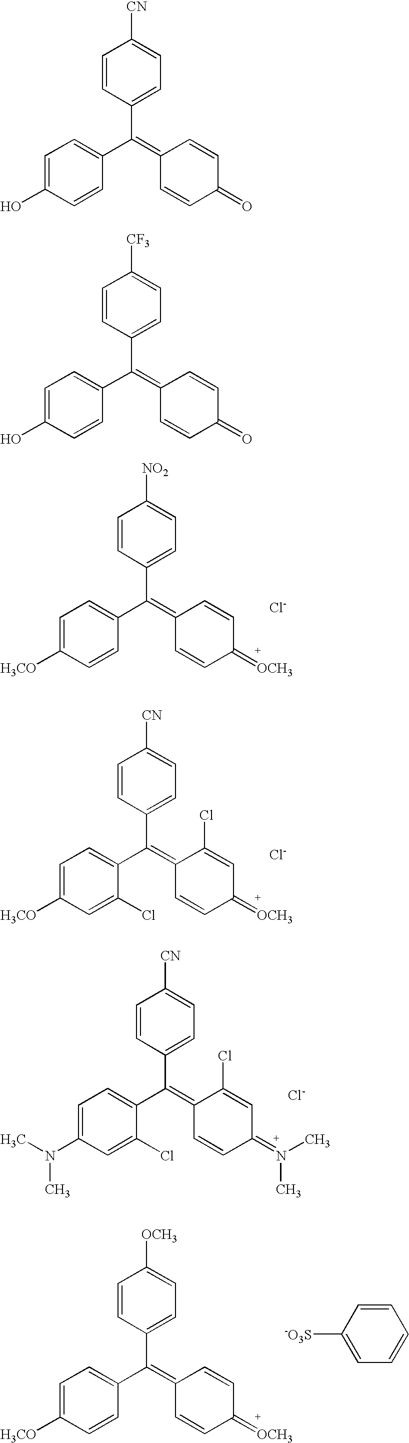

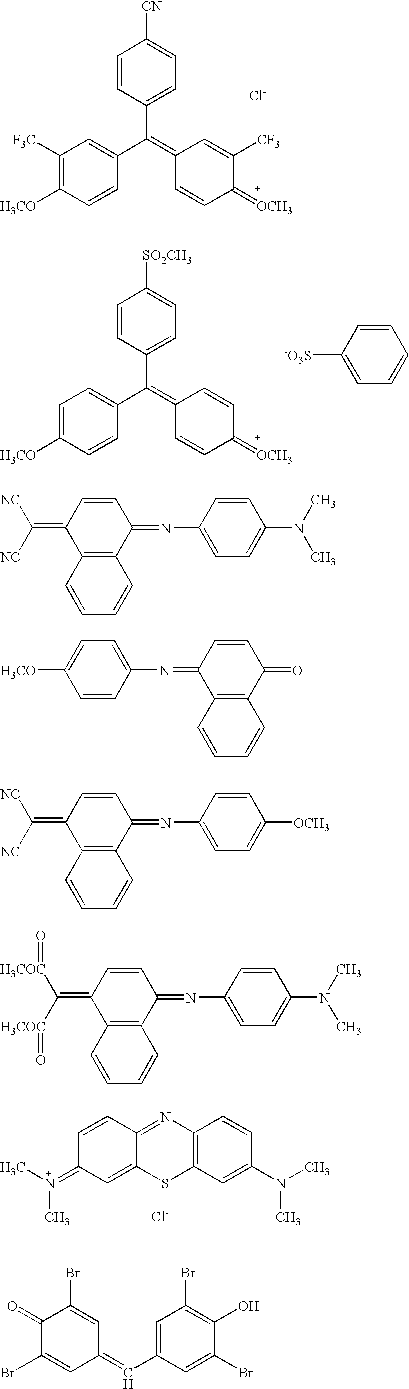

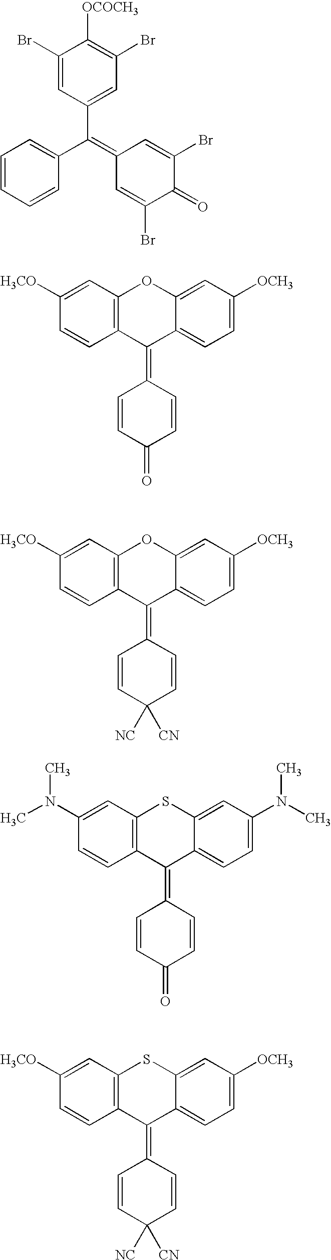

Among the above-mentioned compounds, diarylmethane and triarylmethane colorants are most preferred, and particularly preferred are triarylmethane colorants.

The compound which undergoes color change upon oxidation or reduction according to the invention may be used either alone or in combination of two or more of those compounds.

This compound is preferably used in an amount ranging from 1 μmol/m² to 10 mmol/m², and more preferably 10 μmol/m² to 1 mmol/m². Good visibility is obtained within these ranges.

<Infrared Absorbent>

The lithographic printing plate precursor of the invention uses an infrared absorbent. The infrared absorbent used in the invention is a dye or a pigment having the maximum absorbance at a wavelength in a range of 760 to 1200 nm.

As such a dye, use may be made of commercially available dyes and those known in the literature such as, for example, “Handbook of Dyes” (the Society of Organic Synthetic Chemistry, ed.(1970)). Specifically, mention may be made of azo dyes, metal complex salt azo dyes, pyrazolone azo dyes, naphthoquinone dyes, anthraquinone dyes, phthalocyanine dyes, carbonium dyes, quinoneimine dyes, methine dyes, cyanine dyes, squalium colorants, pyrylium salts, metal-thiolate complexes and the like.

As preferred dyes, mention may be made of, for example, the cyanine dyes as described in JP-A Nos. 58-125246, 59-84356, 60-78787 and the like; the methine dyes as described in JP-A Nos. 58-173696, 58-181690, 58-194595 and the like; the naphthoquinone dyes as described in JP-A Nos. 58-112793, 58-224793, 59-48187, 59-73996, 60-52940, 60-63744 and the like; the squalium colorants as described in JP-A No. 58-112792 or the like; the cyanine dyes as described in GB No. 434,875; and the like.

Further, the near infrared absorber/sensitizer as described in U.S. Pat. No. 5,156,938 is also most preferably used, and also preferably used are the substituted arylbenzo(thio)pyrylium salts described in U.S. Pat. No. 3,881,924; the trimethine thiapyrylium salts described in JP-A No. 57-142645 (U.S. Pat. No. 4,327,169); the pyrylium-based compounds described in JP-A Nos. 58-181051, 58-220143, 59-41363, 59-84248, 59-84249, 59-146063 and 59-146061; the cyanine colorants described in JP-A No. 59-216146; the pentamethine thiopyrylium salts described in U.S. Pat. No. 4,283,475; or the pyrylium compounds described in JP-B Nos. 5-13514 and 5-19702. Further, other preferred examples of dyes may include the near infrared absorbing dyes as represented by Formula (I) and Formula (II) in U.S. Pat. No. 4,756,993.

Further, other preferred examples of the infrared absorbing colorant of the invention may include specific indolenine cyanine colorants as described in JP-A No. 2002-278057, which are illustrated below.

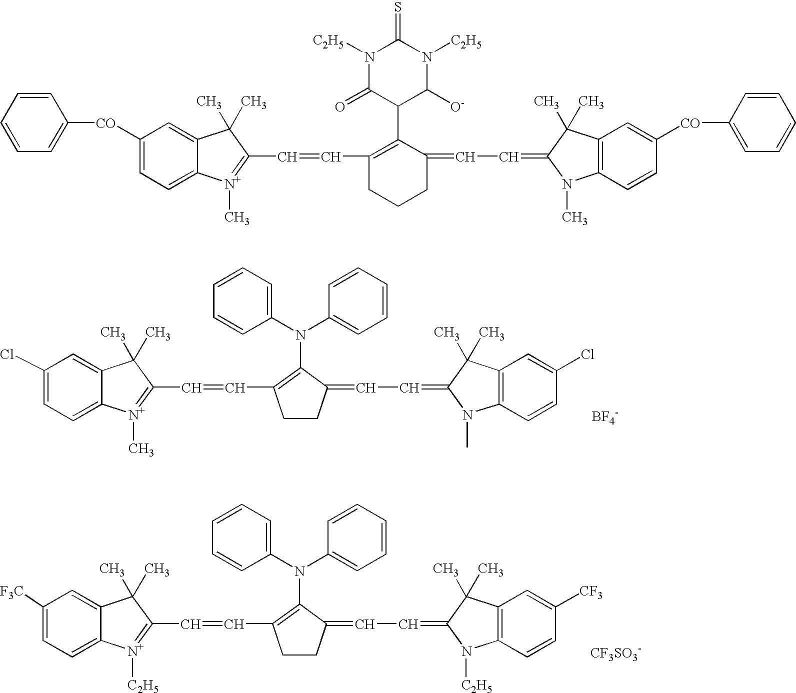

For the pigments used in the invention, use may be made of commercially available pigments and the pigments as described in the handbook of Color Index (C.I.), “Handbook of New Pigments” (Japan Association of Pigment Technology, ed.(1977)), “New Pigment Application Technology” (published by CMC(1986)) and “Printing Ink Technology” (published by CMC(1984)).

The types of pigments may include Black pigments, Yellow pigments, Orange pigments, Brown pigments, Red pigments, Magenta pigments, Blue pigments, Green pigments, fluorescent pigments, metal powder pigments and other polymer-bound pigments. Specifically, insoluble azo pigments, azo lake pigments, condensed azo pigments, chelate azo pigments, phthalocyanine-based pigments, anthraquinone-based pigments, perylene- and perinone-based pigments, thio indigo-based pigments, quinacridone-based pigments, dioxadine-based pigments, isoindolinone-based pigments, quinophthalone-based pigments, hydrated lake pigments, azine pigments, nitroso pigments, nitro pigments, natural pigments, fluorescent pigments, inorganic pigments, carbon black or the like may be used. Among these pigments, preferred is carbon black.

These pigments may be used with or without being subjected to surface treatment. As the method of surface treatment, a method of surface coating with a resin or wax, a method of adhering surfactants, a method of binding a reactive substance (e.g., silane coupling agent, epoxy compound, polyisocyanate, etc.) onto the pigment surface o the like may be envisaged. The above-mentioned methods for surface treatment are described in “Properties and Application of Metal Soaps” (Saiwai Shobo Co., Ltd.), “Printing Ink Technology” (published by CMC(1984)) and “New Pigment Application Technology” (published by CMC(1986)).

The particle diameter of the pigments is preferably in a range of 0.01 to 10 μm, more preferably in the range 0.05 to 1 μm, and particularly preferably in the range 0.1 to 1 μm. Within these ranges, good stability of the pigment dispersion in the coating liquid for the photosensitive-thermosensitive layer and good uniformity in the photosensitive-thermosensitive layer are obtained.

For the method of dispersing pigments, known dispersion techniques used in the manufacture of ink, toner or the like can be used. As the dispersion machine, mention may be made of an ultrasonic dispersion machine, a sand mill, an attritor, a pearl mill, a super mill, a ball mill, an impeller, a disperser, a KD mill, a colloid mill, Dynatron, a three-roll mill, a pressurized kneader and the like. Details can be found in “New Pigment Application Technology” (published by CMC (1986)).

Among the above-described subjects, compounds appropriate for combination with the compound which undergoes color change upon oxidation or reduction will be explained in detail.

A. Infrared Absorbent to be Combined with the Compound which Undergoes Color Change upon Oxidation

The infrared absorbent preferable in the combination with the compound which undergoes color change upon oxidation is preferably a compound having a low excited reduction potential (Ered*) of the infrared absorbent. Effectively used ones among such compounds are various colorants such as cyanine colorants, pyrylium and thiopyrylium colorants. Specific examples of these compounds will be presented in the following.

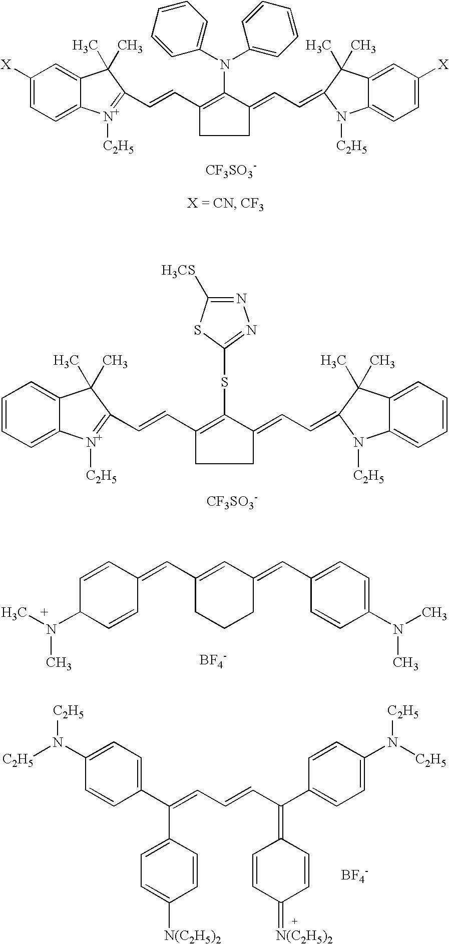

The infrared absorbent is combined with the compound which undergoes color change upon oxidation such that the potential difference between the oxidation potential (Eox) of the compound which undergoes color change upon oxidation and the excited reduction potential (Ered*) of the infrared absorbent (Eox-Ered*) is preferably 0.1 or more, more preferably 0.2 or more, and even more preferably 0.3 or more.

B. Infrared Absorbent to be Combined with the Compound which Undergoes Color Change upon Reduction

The infrared absorbent preferable in the combination with the compound which undergoes color change upon reduction is preferably a compound having a high excited oxidation potential (Eox*) of the infrared absorbent. Effectively used ones among such compounds are various colorants such as cyanine colorants, melocyanine colorants and oxonol colorants. Specific examples of these compounds will be presented in the following.

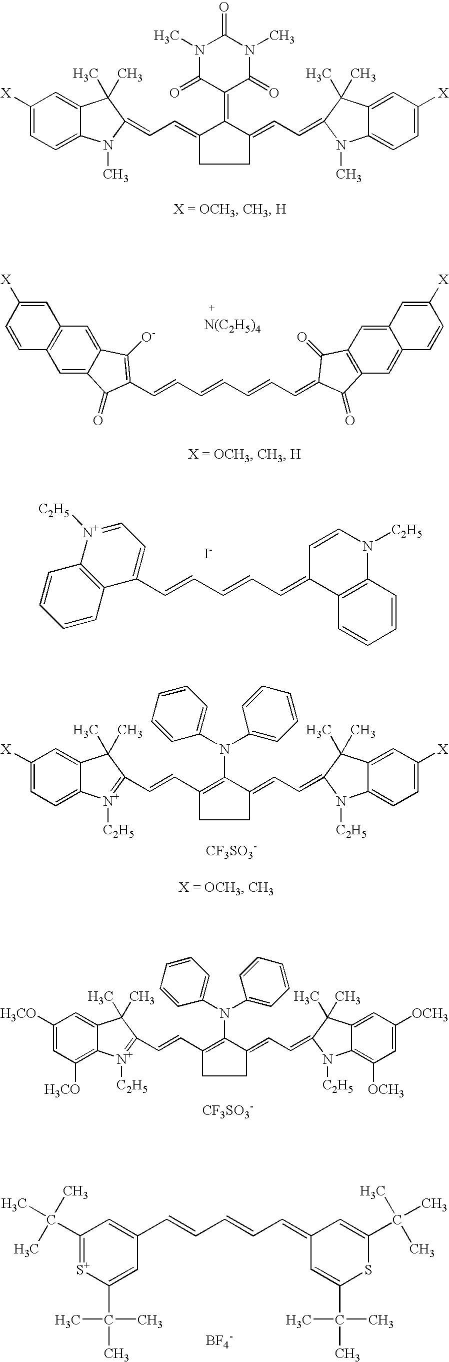

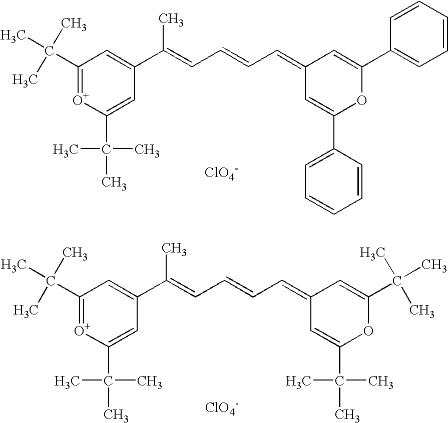

The infrared absorbent is combined with the compound which undergoes color change upon reduction such that the potential difference between the reduction potential (Ered) of the compound which undergoes color change upon reduction and the excited oxidation potential (Eox*) of the infrared absorbent (Eox*-Ered) is preferably 0.1 or more, more preferably 0.2 or more, and even more preferably 0.3 or more.

Such infrared absorbent may be added into the same layer together with other components or may be added into another layer provided thereon. It may also be added as encapsulated in the microcapsules described below.

However, the infrared absorbent which constitutes the reaction system to be burned is preferably contained in the same layer or in the same microcapsules with the compound which undergoes color change upon oxidation or reduction from the viewpoint that good visibility can be obtained.

Further, the infrared absorbent of the invention may be used either alone or in combination of two or more compounds.

The infrared absorbent is added in an amount such that when a negative-type lithographic printing plate precursor has been prepared, the absorbance at the maximum absorption wavelength of the photosensitive-thermosensitive layer in the wavelength range of 760 to 1200 nm preferably lies in a range of 0.3 to 1.2, and more preferably in the range 0.4 to 1.1, as measured by the reflection measurement technique. Within these ranges, polymerization reaction is carried out uniformly along the direction of depth of the photosensitive-thermosensitive layer, and good film strength in the image area and close adhesion to the support are obtained.

The absorbance of the photosensitive-thermosensitive layer can be adjusted by means of the amount of the infrared absorbent to be added into the photosensitive-thermosensitive layer and of the thickness of the photosensitive-thermosensitive layer. Measurement of the absorbance may be implemented by any related-art method. As such method for measurement, mention may be made of, for example, a method of forming, on a reflective support such as aluminum or the like, a photosensitive-thermosensitive layer of an appropriately predetermined thickness in a range such that the amount of the coating after drying is required for a lithographic printing plate and measuring the reflection concentration with an optical densitometer; a method of measuring with a spectrophotometer by the reflection technique using an integrating sphere; or the like.

(Elements for the Formation of Printed Images)

The element that can be favorably used in the formation of printed images in the photosensitive-thermosensitive layer of the invention may be any of (A) an image-forming element employing radical polymerization and (B) an image-forming element employing thermal fusion or thermal reaction of a hydrophobized precursor. Now, these elements will be explained.

(A) Image-Forming Element Employing Radical Polymerization

Regarding an image-forming element employing radical polymerization, the photosensitive-thermosensitive layer of the invention comprises, in addition to the above-mentioned color-changing agent or color-changing system, a radical-polymerizable compound and a radical generator.

The radical polymerization-based element has high sensitivity to image formation, thus being able to effectively distribute the light energy of exposure to the formation of an image to be burned, and is more preferable in obtaining a burned image having large differences in brightness.

<Radical-Polymerizable Compounds>

The photosensitive-thermosensitive layer of the invention preferably comprises a radical-polymerizable compound (hereinafter, simply referred to as a polymerizable compound) for effecting an efficient curing reaction. The radical-polymerizable compound that can be used for the invention is an addition-polymerizable compound having at least one ethylenically unsaturated double bond, and is selected from those compounds having at least one, preferably two or more, ethylenically unsaturated bonds. The family of such compounds is well known in the art pertinent to the invention and can be used for the invention without particular limitation. They are in the chemical form of, for example, a monomer, a prepolymer, that is, a dimer, a trimer and an oligomer, or a mixture thereof and copolymer thereof. Examples of such monomers and copolymers thereof may include unsaturated carboxylic acids (for example, acrylic acid, methacrylic acid, itaconic acid, crotonic acid, isocrotonic acid, maleic acid, etc.) and esters and amides thereof, and preferred are the esters of unsaturated carboxylic acids and of aliphatic polyhydric alcohol compounds, and the amides of unsaturated carboxylic acids and of aliphatic polyvalent amine compounds. Further, the addition products of unsaturated carboxylic esters or amides having nucleophilic substituents such as a hydroxyl group, an amino group, a mercapto group or the like, and of monofunctional or polyfunctional isocyanates or epoxides, and the dehydration condensation products of the foregoing esters or amides with monofunctional or polyfunctional carboxylic acids are also very appropriately used. In addition, the addition products of unsaturated carboxylic esters or amides having electrophilic substituents such as an isocyanate group or an epoxy group and of monofunctional or polyfunctional alcohols, amines or thiols, or the substitution products of unsaturated carboxylic esters having the leaving-group substituents such as a halogen group or a tosyloxy group and of monofunctional or polyfunctional alcohols, amines and thiols are also very appropriate. In another example, it is also possible to use a family of compounds substituted by unsaturated phosphonic acids, styrene, vinyl ethers or the like, in place of the above-described unsaturated carboxylic acids.

Specific examples of the monomeric ester of an aliphatic polyhydric alcohol compound and an unsaturated carboxylic acid may include, as an acrylic ester, ethylene glycol diacrylate, triethylene glycol diacrylate, 1,3-butanediol diacrylate, tetramethylene glycol diacrylate, propylene glycol diacrylate, neopentyl glycol diacrylate, trimethylol propane triacrylate, trimethylol propane tri(acryloyl oxypropyl)ether, trimethylolethane triacrylate, hexanediol diacrylate, 1,4-cyclohexane diol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyl oxyethyl)isocyanurate, polyester acrylate oligomer, EO-modified isocyanuric triacrylate, or the like.

As a methacrylic ester, mention may be made of tetramethylene glycol dimethacrylate, triethylene glycol dimethacrylate, neopentyl glycol dimethacrylate, trimethylol propane trimethacrylate, trimethylol ethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl] dimethylmethane, bis[p-(methacryloxyethoxy)phenyl] dimetylmethane or the like.

As an itaconic ester, there are ethylene glycol diitaconate, propylene glycol diitaconate, 1,3-butanediol diitaconate, 1,4-butanediol diitaconate, tetramethylene glycol diitaconate, pentaerythritol diitaconate, sorbitol tetraitaconate or the like. As a crotonic ester, there are ethylene glycol dicrotonate, tetramethylene glycol dicrotonate, pentaerythritol dicrotonate, sorbitol tetradicrotonate or the like. As an isocrotonic ester, there are ethylene glycol diisocrotonate, pentaerythritol diisocrotonate, sorbitol tetraisocrotonate or the like. As a maleic ester, mention may be made of ethylene glycol dimalate, triethylene glycol dimalate, pentaerythritol dimalate, sorbitol tetramalate or the like.

Other examples of such ester that are also very appropriately used include, for example, the aliphatic alcohol-based esters as described in JP-B No. 51-47334 or JP-A No. 57-196231, those having the aromatic skeleton as described in JP-A No. 59-5240, 59-5241 or 2-226149, or those containing amino groups as described in JP-A No. 1-165613. Further, the above-described monomeric esters may be also used as mixtures.

Specific examples of the monomeric amide of an aliphatic polyvalent amine compound and of an unsaturated carboxylic acid may include methylenebis-acrylamide, methylenebis-methacrylamide, 1,6-hexamethylenebis-acrylamide, 1,6-hexamethylenebis-methacrylamide, diethylenetriamine trisacrylamide, xylylenebis acrylamide, xylylenebis mehacrylamide and the like. Other preferred examples of such amide-based monomer may include those having the cyclohexylene structure as described in JP-B No. 54-21726.

Further, also preferred is the urethane-based addition-polymerizable compounds prepared from the addition reaction between an isocyanate group and a hydroxyl group, and specific examples thereof may include, for example, the vinyl urethane compounds containing two or more polymerizable vinyl groups in a molecule, which are prepared by adding a vinyl monomer containing a hydroxyl group as represented by the following Formula (a), to a polyisocyanate compound having two or more isocyanate groups in a molecule as described in JP-B No. 48-41708, and the like:
CH₂═C(R₄)COOCH₂CH(R₅)OH (a)
wherein R₄ and R₅ represent H or CH₃.

In addition, also preferred are the urethane acrylates as described in JP-A No. 51-37193, JP-B Nos. 2-32293 and 2-16765, or the compounds having the ethylene oxide-based structure as described in JP-B Nos. 58-49860, 56-17654, 62-39417 and 62-39418. Moreover, the use of the addition-polymerizable compounds having an amino structure or a sulfide structure in the molecule as described in JP-A Nos. 63-277653, 63-260909 and 1-105238 can result in a photopolymerizable composition with an excellent photosensitization speed.

Other examples may include polyfunctional acrylates or methacrylates such as the polyester acrylates, the epoxy acrylates resulting from a reaction between an epoxy resin and a (meth)acrylic acid, or the like, as respectively described in JP-A No. 48-64183, JP-B Nos. 49-43191 and 52-30490. Mention may be also made of the specific unsaturated compounds described in JP-B Nos. 46-43946, 1-40337 and 1-40336, the vinylphosphonic acid-based compounds described in JP-A No. 2-25493, or the like. In some cases, the structure containing a perfluoroalkyl group as described in JP-A No. 61-22048 may be appropriately used. Furthermore, use can be made of those introduced as photocurable monomers and oligomers in the Journal of the Adhesion Society of Japan, Vol. 20, No. 7, p. 300-308 (1984).

For these addition-polymerizable compounds, the details of the method of using them such as the compound structure, individual or combined use, the amount of addition or the like may be arbitrarily determined according to the final performance design for the lithographic printing plate precursor. For example, the terms are selected in the following aspects.

In the aspect of sensitivity, a structure having a high content of unsaturations per molecule is preferred, and in most cases, a functionality of two or more is preferred. Also, in order to increase the strength of the image area, namely, the cured film, a functionality of three or more is preferred, and also effective is the method of balancing between the sensitivity and the strength by using compounds with different functionalities or different polymerizable groups (for example, acrylic esters, methacrylic esters, styrene-based compounds, vinyl ether-based compounds) in combination.

Further, in the aspect of compatibility and dispersibility with the other components in the photosensitive-thermosensitive layer (for example, a binder polymer, an initiator, a coloring agent, etc.), the selection and the use of addition-polymerizable compounds are important factors, and in certain cases, compatibility can be improved by, for example, the use of low purity compounds or the combined use of two or more compounds. Selection of a specific structure under the purpose of improving the close adherence to the substrate or to the overcoat layer, etc. described later is also possible.

The polymerizable compounds are used preferably in a range of 5 to 80% by mass, and more preferably 25 to 75% by mass, with respect to the involatile components in the photosensitive-thermosensitive layer. Further, these compounds may be used either alone or in combination of two or more species. Other aspects in the method of using the addition-polymerizable compounds are such that the structure, the blending and the amount of addition can be appropriately selected from the viewpoint of the extent of polymerization inhibition according to oxygen, resolution, clouding, change in the refractive index, surface adhesiveness or the like. Moreover, if appropriate, the techniques of layer construction and coating as referred to as undercoating and overcoating may be also performed.

<Radical Polymerization Initiators>

The radical polymerization initiator as used in the invention means a compound which generates radicals by light, heat or both energy forms, and initiate and promote polymerization of the compounds having polymerizable unsaturations. As the polymerization initiator that can be used in the invention, mention may be made of any known thermal polymerization initiators, compounds having bonds with small dissociation energy, photopolymerization initiators or the like. Among these, a preferably used radical polymerization initiator according to the invention is a compound generating radicals by heat energy. Now, a more detailed explanation will be given on the radical polymerization initiator used in the invention. These radical polymerization initiators can be used either alone or in combination of two or more species.

Such radical polymerization initiator may include, for example, an organic halogen compound, a carbonyl compound, organic peroxides, an azo-based compound, an azide compound, a metallocene compound, a hexaaryl biimidazole compound, an organic boron compound, a disulfone compound, an oxime ester compound and an onium salt compound.

As the organic halogen compound, mention may be made specifically of the compounds described in Wakabayashi, et al., “Bull. Chem. Soc. Japan” 42, 2924 (1969), U.S. Pat. No. 3,905,815, JP-B No. 46-4605, JP-A Nos. 48-36281, 53-133428, 55-32070, 60-239736, 61-169835, 61-169837, 62-58241, 62-212401, 63-70243 and 63-298339, and M. P. Hutt, “Journal of Heterocyclic Chemistry” 1(No. 3), (1970). Among these, the oxazole compounds with substituted trihalomethyl group and s-triazine compounds are very appropriate.

More preferably, mention may be made of the s-triazine derivatives in which at least one mono-, di- or trihalogen-substituted methyl group is attached to the s-triazine ring, specifically for example, 2,4,6-tris(monochloromethyl)-s-triazine, 2,4,6-tris(dichloromethyl)-s-triazine, 2,4,6-tris(trichloromethyl)-s-triazine, 2-methyl-4,6-bis(trichloromethyl)-s-triazine, 2-n-propyl-4,6-bis(trichloromethyl)-s-triazine, 2-(α,α,β-trichloroethyl)-4,6-bis(trichloromethyl)-s-triazine, 2-phenyl-4,6-bis(trichloromethyl)-s-triazine, 2-(p-methoxyphenyl)-4,6-bis(trichloromethyl)-s-triazine, 2-(3,4-epoxyphenyl)-4,6-bis(trichloromethyl)-s-triazine, 2-(p-chlorophenyl)-4,6-bis(trichloromethyl)-s-triazine, 2-[1-(p-methoxyphenyl)-2,4-butadienyl]-4,6-bis(trichloromethyl)-s-triazine, 2-styryl-4,6-bis(trichloromethyl)-s-triazine, 2-(p-methoxystyryl)-4,6-bis(trichloromethyl)-s-triazine, 2-(p-1-propyl oxystyryl)-4,6-bis(trichloromethyl)-s-triazine, 2-(p-tolyl)-4,6-bis(trichloromethyl)-s-triazine, 2-(4-nathoxynaphthyl)-4,6-bis(trichloromethyl)-s-triazine, 2-phenylthio-4,6-bis(trichloromethyl)-s-triazine, 2-benzylthio-4,6-bis(trichloromethyl)-s-triazine, 2,4,6-tris(dibromomethyl)-s-triazine, 2,4,6-tris(tribromomethyl)-s-triazine, 2-methyl-4,6-bis(tribromomethyl)-s-triazine, 2-methoxy-4,6-bis(tribromomethyl)-s-triazine, or the like.

As the carbonyl compound, mention may be made of benzophenone derivatives such as benzophenone, Michier's ketone, 2-methylbenzophenone, 3-methylbenzophenone, 4-methylbenzophenone, 2-chlorobenzophenone, 4-bromobenzophenone, 2-carboxybenzophenone or the like; acetophenone derivatives such as 2,2-dimethoxy-2-phenylacetophenone, 2,2-diethoxyacetophenone, 1-hydroxy cyclohexylphenyl ketone, α-hydroxy-2-methylphenyl propanone, 1-hydroxy-1-methylethyl-(p-isopropylphenyl) ketone, 1-hydroxy-1-(p-dodecylphenyl) ketone, 2-methyl-(4′-(methylthio)phenyl)-2-morpholino-1-propanone, 1,1,1-trichloromethyl-(p-butylphenyl) ketone or the like; thioxantone derivatives such as thioxantone, 2-ethyl thioxantone, 2-isopropyl thioxantone, 2-chlorothioxantone, 2,4-dimethyl thioxantone, 2,4-diethyl thioxantone, 2,4-diisopropyl thioxantone or the like; and benzoic ester derivatives such as ethyl p-dimethylaminobenzoic acid ester, ethyl p-diethylaminobenzoic acid ester or the like.

As the azo-based compound, for example the azo compounds and the like described in JP-A No. 8-108621 can be used.

As the organic peroxide, mention may be made of, for example, trimethylcyclohexanone peroxide, acetylacetone peroxide, 1,1-bis(tert-butylperoxy)-3,3,5-trimethylcyclohexane, 1,1-bis(tert-butylperoxy)cyclohexane, 2,2-bis(tert-butylperoxy)butane, tert-butylhydroperoxide, cumene hydroperoxide, diisopropylene benzene hydroperoxide, 2,5-dimethylhexane-2,5-dihydroperoxide, 1,1,3,3-tetramethylbutylhydroperoxide, tert-butylcumylperoxide, dicumylperoxide, 2,5-dimethyl-2,5-di(tert-butylperoxy)hexane, 2,5-oxanoyl peroxide, succinic acid peroxide, benzoyl peroxide, 2,4-dichlorobenzoyl peroxide, diisopropyl peroxydicarbonate, di-2-ethylhexyl peroxydicarbonate, di-2-ethoxyethyl peroxydicarbonate, dimethoxyisopropyl peroxydicarbonate, di-(3-methyl-3-methoxybutyl) peroxydicarbonate, tert-butyl peroxyacetate, tert-butyl peroxypivalate, tert-butyl peroxyneodecanoate, tert-butyl peroxyoctanoate, tert-butyl peroxylaurate, tosyl carbonate, 3,3′,4,4′-tetra(t-butyl peroxycarbonyl)benzophenone, 3,3′,4,4′-tetra(t-hexyl peroxycarbonyl)benzophenone, 3,3′,4,4′-tetra(p-isopropylcumyl peroxycarbonyl)benzophenone, carbonyl di(t-butylperoxy dihydrogen diphthalate), carbonyl di(t-hexylperoxy dihydrogen diphthalate) or the like.

As the metallocene compound, mention may be made of the various titanocene compounds as described in JP-A Nos. 59-152396, 61-151197, 63-41484, 2-249, 2-4705 and 5-83588, for example, di-cyclopentadienyl-Ti-bis-phenyl, dicyclopentadienyl-Ti-bis-2,6-difluorophen-1-yl, dicyclopentadienyl-Ti-bis-2,4-difluorophen-1-yl, dicyclopentadienyl-Ti-bis-2,4,6-trifluoropheny-1-yl, dicylcopentadienyl-Ti-bis-2,3,5,6-tetrafluorophen-1-yl, dicylcopentadienyl-Ti-bis-2,3,4,5,6-pentafluorophen-1-yl, dimethylcyclopentadienyl-Ti-bis-2,6-difluorophen-1-yl, dimethylcyclopentadienyl-Ti-bis-2,4,6-trifluorophen-1-yl, dimethylcyclopentadienyl-Ti-bis-2,3,5,6-tetrafluorophen-1-yl, dimethylcyclopentadienyl-Ti-bis-2,3,4,5,6-pentafluorophen-1-yl, the iron-arene complex described in JP-A Nos. 1-304453 and 1-152109, or the like.

As the hexaaryl biimidazole compound, mention may be made of, for example, various compounds described in JP-B No. 6-29285 and U.S. Pat. Nos. 3,479,185, 4,311,783 and 4,622,286, in particular, 2,2′-bis(o-chlorophenyl)-4,4′,5,5′-tetraphenyl biimidazole, 2,2′-bis(o-bromophenyl)-4,4′-5,5′-tetraphenyl biimidazole, 2,2′-bis(o,p-dichlorophenyl)-4,4′,5,5′-tetraphenyl biimidazole, 2,2′-bis(o-chlorophenyl)-4,4′,5,5′-tetra(m-methoxyphenyl) biimidazole, 2,2′-bis(o,o-dichlorophenyl)-4,4′,5, 5′-tetraphenyl biimidazole, 2,2′-bis(o-nitrophenyl)-4,4′,5,5′-tetraphenyl biimidazole, 2,2′-bis(o-methylphenyl)-4,4′,5,5′-tetraphenyl biimidazole, 2,2′-bis(o-trifluorophenyl)-4,4′,5,5′-tetraphenyl biimidazole or the like.

As the organic boron compound, mention may be made of, for example, the organic boric acid salts as described in JP-A Nos. 62-143044, 62-150242, 9-188685, 9-188686, 9-188710, 2000-131837 and 2002-107916, Japanese Patent No. 2764769, JP-A No. 2002-116539 and Kunz, Martin, “Rad Tech′ 98. Proceeding Apr. 19-22, 1998, Chicago” and the like; the organic boron-sulfonium complexes or the organic boron-oxosulfonium complexes as described in JP-A Nos. 6-157623, 6-175564 and 6-175561; the organic boron-iodonium complexes as described in JP-A Nos. 6-175554 and 6-175553; the organic boron-phosphonium complexes as described in JP-A No. 9-188710, the organic boron-transition metal coordination complexes as described in JP-A Nos. 6-348011, 7-128785, 7-140589, 7-306527 and 7-292014; or the like.

As the disulfone compounds, mention may be made of, the compounds as described in JP-A Nos. 61-166544 and 2003-328465, and the others.

As the oxime ester compound, mention may be made of the compounds described in J.C.S. Perkin II (1979) 1653-1660, J.C.S. Perkin II (1979) 156-162, Journal of Photopolymer Science and Technology (1995) 202-232 and in JP-A No. 2000-66385, the compounds described in JP-A No. 2000-80068, and specifically the compounds represented by the following structural formulae:

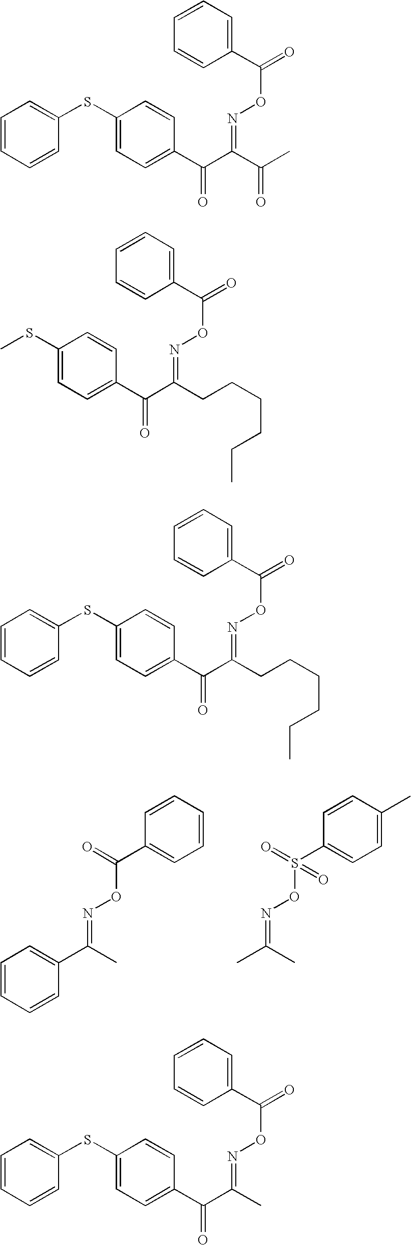

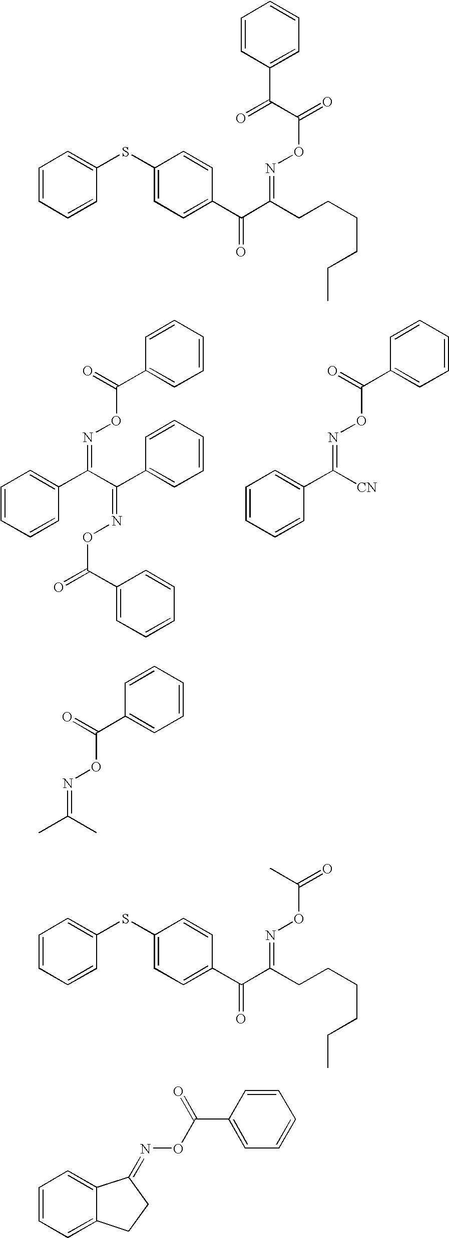

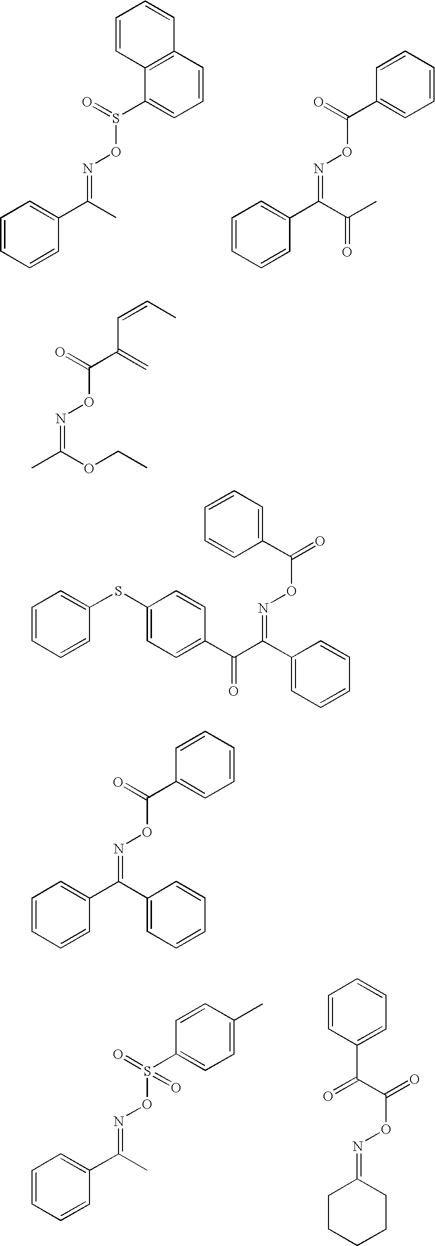

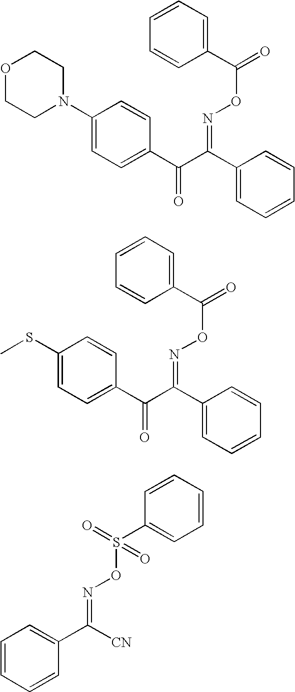

As the onium salt compound, mention may be made of, for example, the diazonium salts as described in S. I. Schlesinger, Photogr. Sci. Eng., 18, 387 (1974) and T. S. Bal et al., Polymer, 21, 423 (1980); the ammonium salts as described in U.S. Pat. No. 4,069,055, JP-A No. 4-365049 or the like; the phosphonium salts as described in U.S. Pat. Nos. 4,069,055 and 4,069,056; the iodonium salts as described in EP No. 104,143, U.S. Pat. Nos. 339,049 and 410,201 and JP-A Nos. 2-150848 and 2-296514; the sulfonium salts as described in EP No. 370,693, 390,214, 233,567, 297,443 and 297,442, U.S. Pat. Nos. 4,933,377, 161,811, 410,201, 339,049, 4,760,013, 4,734,444 and 2,833,827, DE Nos. 2,904,626, 3,604,580 and 3,604,581; the celenonium salt as described in J. V. Crivello et al., Macromolecules, 10(6), 1307 (1977) and J. V. Crivello et al., J. Polymer Sci., Polymer Chem. Ed., 17, 1047 (1979); the arsonium salt as described in C. S. Wen et al., Teh Proc. Conf. Rad. Curing ASIA, p. 478, Tokyo, October (1988); or the like.

In particular, from the viewpoints of reactivity and stability, the oxime ester compounds or the onium salts (diazonium salts, iodonium salts or sulfonium salts) may be favorably mentioned.

The onium salts used favorably in the invention are the onium salts represented by the following formulae (RI-I) to (RI-III):

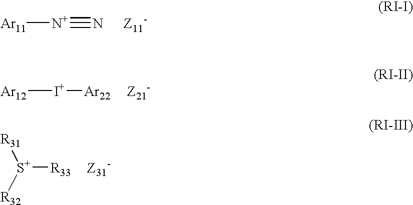

In Formula (RI-I), Ar₁₁, represents an aryl group having up to 20 carbon atoms and optionally 1 to 6 substituents, and the preferred substituents may include an alkyl group having 1 to 12 carbon atoms, an alkenyl group having 1 to 12 carbon atoms, an alkynyl group having 1 to 12 carbon atoms, an aryl group having 1 to 12 carbon atoms, an alkoxy group having 1 to 12 carbon atoms, an aryloxy group having 1 to 12 carbon atoms, a halogen atom, an alkylamino group having 1 to 12 carbon atoms, a dialkylamino group having 1 to 12 carbon atoms, an alkylamide group or an arylamide group having 1 to 12 carbon atoms, a carbonyl group, a carboxyl group, a cyano group, a sulfonyl group, a thioalkyl group having 1 to 12 carbon atoms, and a thioaryl group having 1 to 12 carbon atoms. Z₁₁⁻ represents a monovalent anion and specific examples thereof may include a halogen ion, a perchlorate ion, a hexafluorophosphate ion, a tetrafluoroborate ion, a sulfonate ion, a sulfinate ion, a thiosulfonate ion and a sulfate ion. Among these, a perchlorate ion, a hexafluorophosphate ion, a tetrafluoroborate ion, a sulfonate ion and a sulfinate ion are preferred in terms of stability.

In Formula (RI-II), Ar₂₁ and Ar₂₂ each independently represent an aryl group having up to 20 carbon atoms and optionally 1 to 6 substituents, and the preferred substituents may include an alkyl group having 1 to 12 carbon atoms, an alkenyl group having 1 to 12 carbon atoms, an alkynyl group having 1 to 12 carbon atoms, an aryl group having 1 to 12 carbon atoms, an alkoxy group having 1 to 12 carbon atoms, an aryloxy group having 1 to 12 carbon atoms, a halogen atom, an alkylamino group having 1 to 12 carbon atoms, a dialkylamino group having 1 to 12 carbon atoms, an alkylamide group or an arylamide group having 1 to 12 carbon atoms, a carbonyl group, a carboxyl group, a cyano group, a sulfonyl group, a thioalkyl group having 1 to 12 carbon atoms, and a thioaryl group having 1 to 12 carbon atoms. Z₂₁ − represents a monovalent anion, and specific examples thereof may include a halogen ion, a perchlorate ion, a hexafluorophosphate ion, a tetrafluoroborate ion, a sulfonate ion, a sulfinate ion, a thiosulfonate ion and a sulfate ion. Among these, a perchlorate ion, a hexafluorophosphate ion, a tetrafluoroborate ion, a sulfonate ion, a sulfinate ion and a carboxylate ion are preferred in terms of stability and reactivity.

In Formula (RI-III), R₃₁, R₃₂ and R₃₃ each independently represent an aryl, alkyl, alkenyl or alkynyl group having up to 20 carbon atoms and optionally 1 to 6 substituents, and the preferred substituents may include an alkyl group having 1 to 12 carbon atoms, an alkenyl group having 1 to 12 carbon atoms, an alkynyl group having 1 to 12 carbon atoms, an aryl group having 1 to 12 carbon atoms, an alkoxy group having 1 to 12 carbon atoms, an aryloxy group having 1 to 12 carbon atoms, a halogen atom, an alkylamino group having 1 to 12 carbon atoms, a dialkylamino group having 1 to 12 carbon atoms, an alkylamide group or an arylamide group having 1 to 12 carbon atoms, a carbonyl group, a carboxyl group, a cyano group, a sulfonyl group, a thioalkyl group having 1 to 12 carbon atoms, and a thioaryl group having 1 to 12 carbon atoms. Z₃₁⁻ represents a monovalent anion, and specific examples thereof may include a halogen ion, a perchlorate ion, a hexafluorophosphate ion, a tetrafluoroborate ion, a sulfonate ion, a sulfinate ion, a thiosulfonate ion and a sulfate ion. Among these, a perchlorate ion, a hexafluorophosphate ion, a tetrafluoroborate ion, a sulfonate ion, a sulfinate ion and a carboxylate ion are preferred in terms of stability and reactivity. More preferred is the carboxylate ion as described in JP-A No. 2001-343742, and particularly preferred is the carboxylate ion as described in JP-A No. 2002-148790.

Specific examples of the compounds represented by the above formulae (RI-I) to (RI-III) are presented below, but they are not intended to limit the invention.

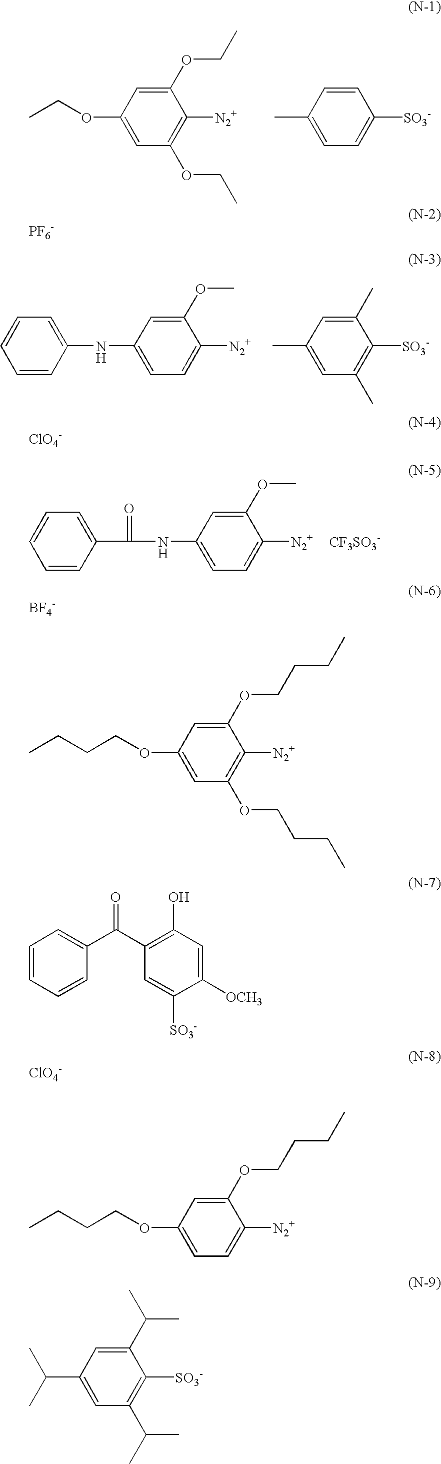

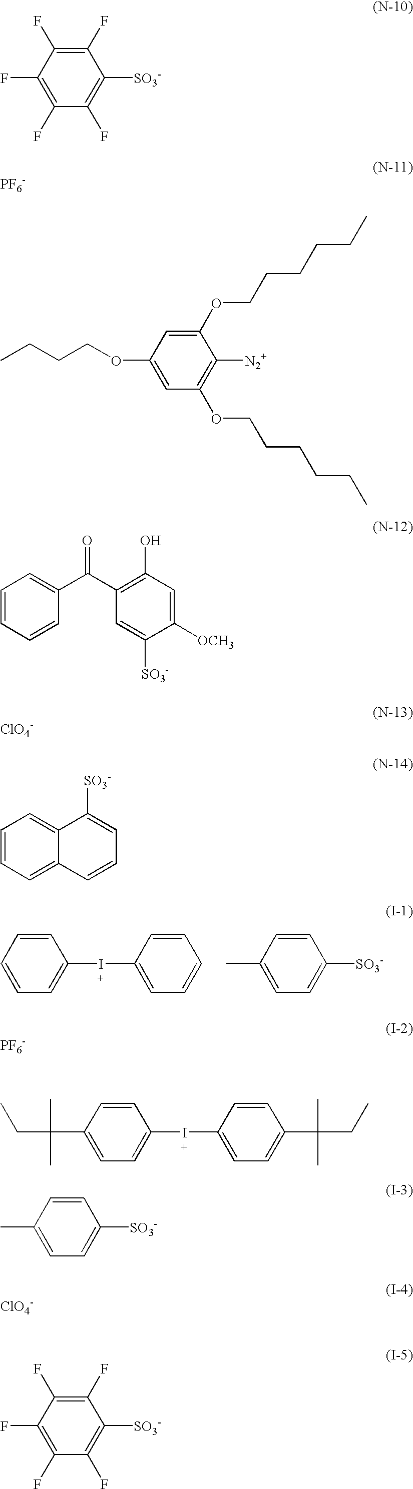

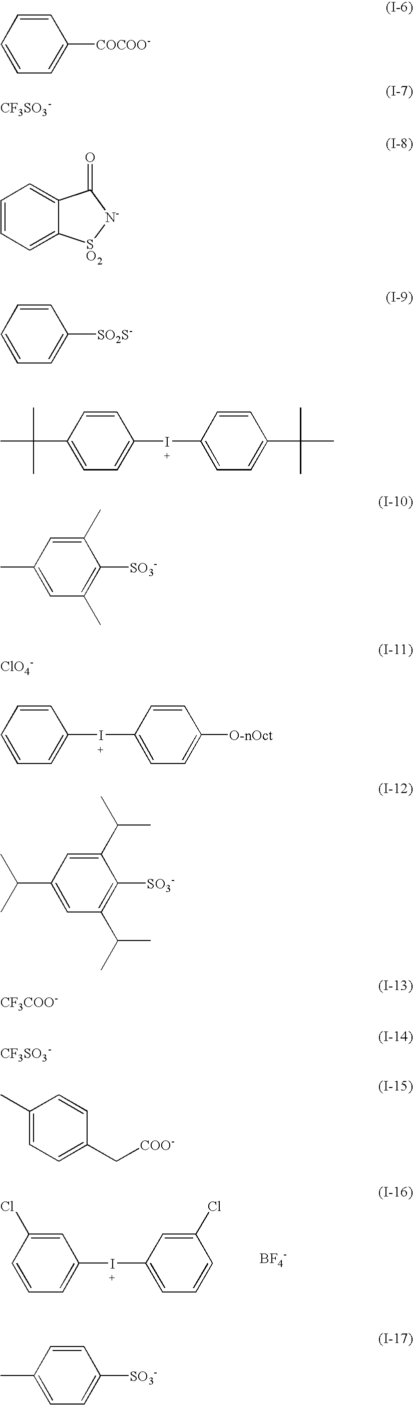

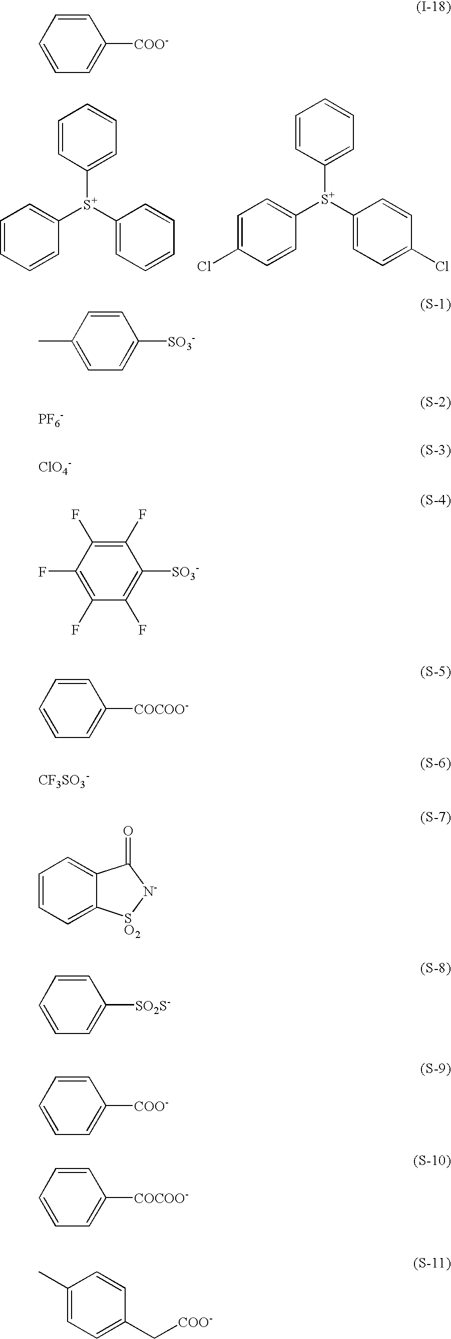

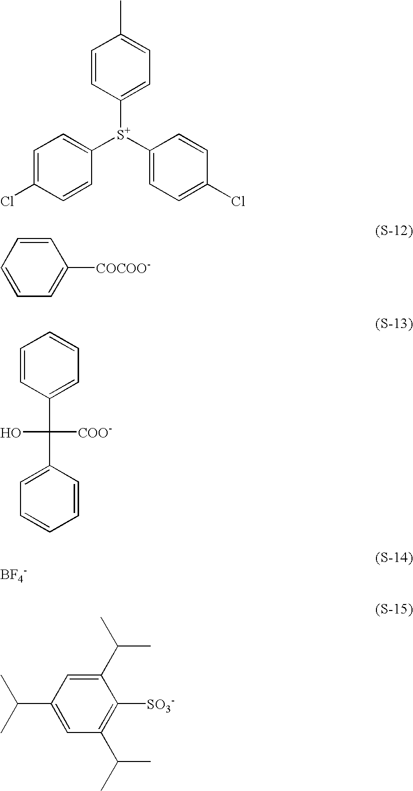

These radical polymerization initiators can be added in a proportion of preferably 0.1 to 50% by mass, more preferably 0.5 to 30% by mass, and even more preferably 1 to 20% by mass, with respect to the total solids constituting the photosensitive-thermosensitive layer. Within these ranges, good anti-contamination in the non-image area during printing as well as good sensitivity can be obtained. These radical polymerization initiators may be used either alone or in combination of two or more species. Further, these radical polymerization initiators may be added into the same layer with other components or into a different layer provided thereon.

<Other Photosensitive-Thermosensitive Layer Components>

The radical polymerization-based photosensitive-thermosensitive layer of the invention may also contain additives such as a binder polymer, a surfactant, a polymerization inhibitor, a higher fatty acid derivative, a plasticizer, an inorganic microparticle, a low molecular hydrophilic compound or the like as appropriate. An explanation will be given on these hereinbelow.

<Binder Polymers>

The photosensitive-thermosensitive layer of the invention can contain a binder polymer. For the binder polymer that can be used in the invention, any known conventional ones can be used without limitation, and an organic polymer in the linear form having film-forming property is preferred. Examples of such binder polymer may include acrylic resins, polyvinyl acetal resins, polyurethane resins, polyurea resins, polyimide resins, polyamide resins, epoxy resins, methacrylic resins, polystyrene-based resins, novolac phenol-based resins, polyester resins, synthetic rubbers and natural rubbers.

The binder polymer preferably has crosslinkability for improving the film strength of the image area. In order to impart crosslinkability to the binder polymer, it is preferable to introduce a crosslinkable functional group such as ethylenic unsaturation or the like into the backbone or the side chain of the polymer. The crosslinkable functional group may also be introduced by copolymerization.

Examples of the polymer having ethylenic unsaturation in the backbone of the molecule may include poly-1,4-butadiene, poly-1,4-isoprene and the like.

An example of the polymer having ethylenic unsaturation in the side chain of the molecule may be an ester or amide polymer of acrylic acid or methacrylic acid, which has ethylenic unsaturation in the ester or amide residue (R in —COOR or —CONHR).

As examples of the residue (said R) having ethylenic unsaturation, mention may be made of —(CH₂)ₙCR¹═CR²R³, —(CH₂O)ₙCH₂CR¹═CR²R³, —(CH₂CH₂O)ₙCH₂CR¹═CR²R³, —(CH₂)ₙNH—CO—O—CH₂CR¹═CR²R³, −(CH₂)ₙ—O—CO—CR¹═CR²R³ and —(CH₂CH₂O)₂—X, wherein R¹ to R³ each represent a hydrogen atom, a halogen atom or an alkyl group, an aryl group, an alkoxy group or an aryloxy group respectively having 1 to 20 carbon atoms, and R¹ and R² or R³ may be joined together to form a ring; n represents an integer between 1 and 10; and X represents a dicyclopentadienyl residue.

Specific examples of the ester residue may include —CH₂CH═CH₂ (described in JP-B No. 7-21633), —CH₂CH₂O—CH₂CH═CH₂, —CH₂C(CH₃)═CH₂, —CH₂CH═CH—C₆H₅, —CH₂CH₂OCOCH═CH—C₆H₅, —CH₂CH₂—NHCOO—CH₂CH═CH₂ and —CH₂CH₂O—X, wherein X represents a dicyclopentadientyl residue.

Specific examples of the amide residue may include —CH₂CH═CH₂, —CH₂CH₂—Y, wherein Y represents a cyclohexene residue, and —CH₂CH₂—OCO—CH═CH₂.

Concerning the crosslinkable binder polymer, a free radical (a polymerization-initiating radical, or a growing radical in the course of polymerization of the polymeric compound) is added to the crosslinkable functional group, addition polymerization is effected directly between the polymers or via the polymerization chains of the polymeric compounds, and thereby crosslinking is achieved between the polymeric molecules to finally cure. Or else, an atom in the polymer (for example, a hydrogen atom on a carbon atom adjacent to the functional crosslinking group) is removed by a free radical, subsequently polymeric radicals are generated and joined together, and thereby crosslinking is achieved between the polymeric molecules to finally cure.

The content of the crosslinkable group in the binder polymer (the content of the radical-polymerizable, unsaturated double bond as measured by iodine titration) is preferably 0.1 to 10.0 mmol, more preferably 1.0 to 7.0 mmol, and most preferably 2.0 to 5.5 mmol, with respect to 1 g of the binder polymer. Within these ranges, good sensitivity and good stability on storage are obtained.

Further, from the viewpoint of an improvement in the capability of the ob-board development, the binder polymer preferably has high solubility or dispersibility in ink and/or fountain solution.

In order to improve the solubility or dispersibility in ink, the binder polymer is preferably oleophilic, whereas in order to improve the solubility or dispersibility in a fountain solution, the binder polymer is preferably hydrophilic. For this reason, in the invention, it is effective to use an oleophilic binder polymer and a hydrophilic binder polymer in combination.

As a hydrophilic binder polymer, mention may be favorably made of, for example, those having a hydrophilic group such as a hydroxyl group, a carboxyl group, a carboxylate group, a hydroxyethyl group, a polyoxyethyl group, a hydroxypropyl group, a polyoxypropyl group, an amino group, an aminoethyl group, an aminopropyl group, an ammonium group, an amide group, a carboxymethyl group, a sulfonic group, a phosphoric group or the like.

Specific examples may include gum Arabic, casein, gelatin, starch derivatives, carboxymethyl cellulose and its sodium salt, cellulose acetate, sodium alginate, vinyl acetate-maleic acid copolymers, styrene-maleic acid copolymers, polyacrylic acids and their salts, polymethacrylic acids and their salts, homopolymers and copolymers of hydroxyethyl methacrylate, homopolymers and copolymers of hydroxyethyl acrylate, homopolymers and copolymers of hydroxypropyl methacrylate, homopolymers and copolymers of hydroxypropyl acrylate, homopolymers and copolymers of hydroxybutyl methacrylate homopolymers and copolymers of hydroxybutyl acrylate, polyethylene glycols, hydroxypropylene polymers, polyvinyl alcohols, hydrolyzed polyvinyl acetate having a degree of hydrolysis of 60 mol % or more, and preferably 80 mol % or more, polyvinyl formal, polyvinyl butyral, polyvinyl pyrrolidone, homopolymers and copolymers of acrylamide, homopolymers and copolymers of methacrylamide, homopolymers and copolymers of N-methylol acrylamide, polyvinyl pyrrolidone, alcohol-soluble nylon, polyether of 2,2-bis-(4-hydroxyphenyl)propane and of epichlorohydrin, or the like.

The binder polymer preferably has a weight-average molecular weight of 5,000 or more, and more preferably of 10,000 to 300,000, and has a number-average molecular weight of 1,000 or more, and more preferably of 2,000 to 250,000. The polydispersity (weight-average molecular weight/number-average molecular weight) is preferably 1.1 to 10.

The binder polymer may be preferably any one of a random polymer, a block polymer and a graft polymer, a random polymer being more preferred. Also, the binder polymer may be used either alone or in mixture of two or more species.

The binder polymer can be synthesized by any conventionally known method. As the solvent used for the synthesis, mention may be made of, for example, tetrahydrofuran, ethylene dichloride, cyclohexanone, methyl ethyl ketone, acetone, methanol, ethanol, ethylene glycol monomethyl ether, ethylene glycol monoethyl ether, 2-methoxyethyl acetate, diethylene glycol dimethyl ether, 1-methoxy-2-propanol, 1-methoxy-2-propyl acetate, N,N-dimethyl formamide, N,N-dimethyl acetamide, toluene, ethyl acetate, methyl lactate, ethyl lactate, dimethyl sulfoxide and water. These are used either alone or in mixture of two or more species.

As the radical polymerization initiator used for the synthesis of the binder polymer, known compounds such as azo-based initiators, peroxide initiators or the like may be used.

The content of the binder polymer is preferably 10 to 90% by mass, more preferably 20 to 80% by mass, and even more preferably 30 to 70% by mass, with respect to the total solids in the photosensitive-thermosensitive layer. Within these ranges, it is possible to obtain good strength in the image area and good image formability.

Further, it is preferable to use the polymerizable compound and the binder polymer in a mass proportion of 1/9 to 7/3.

<Surfactants>

In the photosensitive-thermosensitive layer of the invention, surfactants are preferably used in order to promote the property of on-board development at the initiation of printing and to improve the state of the coating surface. For such surfactants, nonionic surfactants, anionic surfactants, cationic surfactants, amphoteric surfactants, fluorine-based surfactants or the like may be mentioned. The surfactants may be used either alone or in combination of two or more species.

The nonionic surfactants used in the invention are not particularly limited and any known ones can be used. For example, mention may be made of polyoxyethylene alkylethers, polyoxyethylene alkylphenylethers, polyoxyethylene polystyryl phenylethers, polyoxyethylene polyoxypropylene alkylethers, glycerin fatty acid partial esters, sorbitan fatty acid partial esters, pentaerythritol fatty acid partial esters, propylene glycol monofatty acid esters, sucrose fatty acid partial esters, polyoxyethylene sorbitan fatty acid partial esters, polyoxyethylene sorbitol fatty acid partial esters, polyethylene glycol fatty acid esters, polyglycerin fatty acid partial esters, polyoxyethyleneated castor oils, polyoxyethylene glycerin fatty acid partial esters, fatty acid diethanol amides, N,N-bis-2-hydroxyalkylamines, polyoxyethylene alkylamine, triethanolamine fatty acid esters, trialkylamine oxide, polyethylene glycol, and copolymers of polyethylene glycol and polypropylene glycol.

The anionic surfactants used in the invention are not particularly limited, and any conventional ones can be used. For example, mention may be made of fatty acid salts, abietic acid salts, hydroxyalkanesulfonic acid salts, alkanesulfonic acid salts, dialkylsulfosuccinic ester salts, straight-chained alkylbenzene sulfonic acid salts, branched-chained alkylbenzene sulfonic acid salts, alkylnaphthalene sulfonic acid salts, alkylphenoxy polyoxyetylene propylsulfonic acid salts, polyoxyethylene alkylsulfophenyl ether salts, sodium N-methyl-N-oleyltaurate, disodium N-alkylsulfosuccinic monoamide, petroleum sulfonic acid salts, beef tallow sulfate, sulfuric ester salts of fatty acid alkyl esters, alkyl sulfuric ester salts, polyoxyethylene alkylether sulfuric esters, fatty acid monoglyceride sulfuric ester salts, polyoxyethylene alkylphenyl ether sulfuric ester salts, polyoxyethylene styrylphenyl ether sulfuric ester salts, alkyl phosphoric ester salts, polyoxyethylene alkylether phosphoric ester salts, polyoxyethylene alkylphenyl ether phosphoric ester salts, partial saponification products of styrene/maleic anhydride copolymers, partial saponification products of olefin/maleic anhydride copolymers, and naphthalene sulfonate formalin condensates.

The cationic surfactants used in the invention are not particularly limited, and any conventional ones can be used. For example, mention may be made of alkylamine salts, quaternary ammonium salts, polyoxyethylene alkylamine salts, and polyethylene polyamine derivatives.

The amphoteric surfactants used in the invention are not particularly limited, and any conventional ones can be used. For example, carboxybetaines, aminocarboxylic acids, sulfobetaines, amino sulfuric esters and imidazolines may be mentioned.

In addition, among the above-described surfactants, those referred to as “polyoxyethylene” may also be read as “polyoxyalkylene” such as polyoxymethylene, polyoxypropylene, polyoxybutylene or the like, and the invention can also make use of those surfactants.

For more preferred surfactants, fluorine-based surfactants containing a perfluoroalkyl group in the molecule may be mentioned. Such fluorine-based surfactants may include, for example, anionic type such as perfluoroalkyl carboxylate, perfluoroalkyl sulfonate, perfluoroalkyl phosphoric esters or the like; amphoteric type-such as perfluoroalkyl betaine or the like; cationic type such as perfluoroalkyl trimethyl ammonium salts or the like; and nonionic type such as perfluoroalkylamine oxide, perfluoroalkyl ethylene oxide adducts, oligomers containing perfluoroalkyl group and hydrophilic group, oligomers containing perfluoroalkyl group and lipophilic group, oligomers containing perfluoroalkyl group, hydrophilic group and lipophilic group, urethane containing perfluoroalkyl group and lipophilic group, or the like. Further, the fluorine-based surfactants as described in JP-A Nos. 62-170950, 62-226143 and 60-168144 are also preferred.

The surfactants can be used either alone or in combination of two or more species.

The content of the surfactants is preferably 0.001 to 10% by mass, and more preferably 0.01 to 7% by mass, with respect to the total solids in the photosensitive-thermosensitive layer.

<Polymerization Inhibitors>

A small amount of thermal polymerization-preventing agent is preferably added to the photosensitive-thermosensitive layer of the invention, in order to prevent unnecessary thermal polymerization of the radical-polymerizable compound (C) during the preparation or storage of the photosensitive-thermosensitive layer.

Examples of such thermal polymerization-preventing agent may be mentioned favorably of hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol), and the aluminum salt of N-nitroso-N-phenylhydroxylamine.

The amount of the thermal polymerization-preventing agent added is preferably about 0.01% to about 5% by mass with respect to the total solids in the photosensitive-thermosensitive layer.

<Higher Fatty Acid Derivatives, Etc.>

In the photosensitive-thermosensitive layer of the invention, higher fatty acid derivatives such as behenic acid, behenic acid amide or the like may be added and localized at the surface of the photosensitive-thermosensitive layer during the course of drying after coating, in order to prevent the inhibition of polymerization by oxygen. The amount of higher fatty acid derivatives added is preferably about 0.1% to about 10% by mass with respect to the total solids in the photosensitive-thermosensitive layer.

<Plasticizers>

The photosensitive-thermosensitive layer of the invention may contain a plasticizer in order to improve the capability of the on-board development.

As such plasticizer, mention may be made preferably of, for example, phthalic esters such as dimethyl phthalate, diethyl phthalate, dibutyl phthalate, diisobutyl phthalate, dioctyl phthalate, octylcapryl phthalate, dicyclohexyl phthalate, ditridecyl phthalate, butylbenzyl phthalate, diisodecyl phthatlate, diaryl phthalate or the like; glycol esters such as dimethyl glycol phthalate, ethylphthalylethyl glycolate, methylphthalylethyl glycolate, butylphthalylbutyl glycolate, triethylene glycol dicaprilic ester or the like; phosphoric esters such as tricresyl phosphate, triphenyl phosphate or the like, aliphatic dibasic acid esters such as diisobutyl adipate, dioctyl adipate, dimethyl sebacate, dibutyl sebacate, dioctyl azelate, dibutyl maleate or the like; polyglycidyl methacrylate, triethyl citrate, glycerin triacetyl ester, butyl laurate, or the like.

The content of the plasticizer is preferably about 30% by mass or less, with respect to the total solids in the photosensitive-thermosensitive layer.

<Inorganic Microparticles>

The photosensitive-thermosensitive layer of the invention may contain inorganic microparticles for the improvement of the cured film strength at the image area and for the improvement of the capability of the on-board development at the non-image area.

As such inorganic microparticles, mention may be made very favorably of, for example, silica, alumina, magnesium oxide, titanium oxide, magnesium carbonate, calcium alginate or mixtures thereof. Even though they may not be photo-thermo convertible, the microparticles can be used for reinforcement of the coating, intensification of the interface-adherence by means of surface roughening, or the like.

Inorganic microparticles have an average particle size of preferably 5 nm to 10 μm, and more preferably 0.5 to 3 μm. In these ranges, they can be stably distributed within the photosensitive-thermosensitive layer to sufficiently maintain the film strength of the photosensitive-thermosensitive layer, and can form a non-image area which has excellent hydrophilicity, making it difficult to be contaminated upon printing.

Such inorganic microparticles as described in the above are easily available as commercial products such as a colloidal silica dispersion or the like.

The content of the inorganic microparticles is preferably 20% by mass or less, and more preferably 10% by mass or less, with respect to the total solids in the photosensitive-thermosensitive layer.

<Low Molecular Hydrophilic Compounds>

The photosensitive-thermosensitive layer of the invention may contain a hydrophilic low molecular compound in order to improve the capability of the on-board development. Examples of the hydrophilic low molecular compound may be mentioned of, as water-soluble organic compounds, glycols such as ethylene glycol, diethylene glycol, triethylene glycol, propylene glycol, dipropylene glycol, tripropylene glycol or the like and ether or ester derivatives thereof; polyhydroxys such as glycerin, pentaerythritol or the like; organic amines such as triethanolamine, diethanolamine, monoethanolamine or the like and salts thereof; organic sulfonates such as toluene sulfonate, benzene sulfonate or the like and salts thereof; organic phosphonates such as phenyl phosphonate or the like and salts thereof; organic carboxylic acids such as tartaric acid, oxalic acid, citric acid, malic acid, lactic acid, gluconic acid, amino acids or the like and salts thereof.

<Formation of the Radical Polymerization Type Photosensitive-Thermosensitive Layer>

According to the invention, several embodiments can be used as the method of incorporating the above-mentioned constituents of the photosensitive-thermosensitive layer into the photosensitive-thermosensitive layer. One is an embodiment of dissolving the constituents in a suitable solvent and coating the solution, for example, as described in JP-A No. 2002-287334, and another is an embodiment of incorporating the constituents of the photosensitive-thermosensitive layer as contained in microcapsules (the microcapsule type photosensitive-thermosensitive layer), for example, as described in JP-A Nos. 2001-277740 and 2001-277742. Moreover, in the microcapsule type photosensitive-thermosensitive layer, the constituents may be incorporated in the outside of microcapsules.

According to the invention, as described earlier, it is preferable to incorporate the compound which undergoes color change upon oxidation or reduction in combination with an infrared absorbent (the reaction system to be burned) into the same microcapsules, in view of obtaining a burned image with good visibility. Further, in a more preferable embodiment, a reaction system of radical-polymerizable compounds, a radical polymerization initiator or the like for forming printed images is separated from the reaction system to be burned by incorporating former into different microcapsules from the microcapsules containing the compound which undergoes color change upon oxidation or reduction in combination with an infrared absorbent, or by adding in the outside of the microcapsules, from the perspective of avoiding inter-inhibition of the reactions between the two systems.

As the method of microencapsulating said constituents of the photosensitive-thermosensitive layer, any known method can be employed. For example, as the method of preparing microcapsules, a method of utilizing coacervation as described in U.S. Pat. Nos. 2,800,457 and 2,800,458; a method of involving interface polymerization as described in U.S. Pat. No. 3,287,154, and JP-B Nos. 38-19574 and 42-446; a method of involving polymer precipitation as described in U.S. Pat. Nos. 3,418,250 and 3,660,304; a method of using the isocyanate polyol wall material as described in U.S. Pat. No. 3,796,669; a method of using the isocyanate wall material as described in U.S. Pat. No. 3,914,511; a method of using the wall-forming materials of the urea-formaldehyde system or the urea-formaldehyde-resorcinol system as described respectively in U.S. Pat. Nos. 4,001,140, 4,087,376 and 4,089,802; a method of using the wall material such as melamine-formaldehyde resin, hydroxycellulose or the like as described in U.S. Pat. No. 4,025,445; an in situ method of involving polymerization of the monomers as described respectively in JP-B Nos. 36-9163 and 51-9079; a method of spray-drying as described in GB No. 930422 and U.S. Pat. No. 3,111,407; a method of electrolytic dispersion freezing as described in GB Nos. 952807 and 967074; or the like may be mentioned, without being limited to these.

The wall of the microcapsules used in the invention preferably has a three-dimensional crosslinked structure and the property of swelling in a solvent. From this point of view, the wall material for the microcapsules is preferably polyurea, polyurethane, polyester, polycarbonate, polyamide and mixtures thereof, polyurea and polyurethane being particularly preferred. Also, a compound having crosslinkable functional group such as the ethylenic unsaturation which can be introduced to the above-mentioned binder polymer may be introduced to the microcapsule wall.

The average particle size of the microcapsule is preferably 0.01 to 3.0 μm, more preferably 0.05 to 2.0 μm, and particularly preferably 0.10 to 1.0 μm. Within these ranges, good resolution and stability over time can be obtained.

The photosensitive-thermosensitive layer of the invention is coated with a coating liquid prepared by dispersing or dissolving the respective components as necessary in a solvent. For the solvent used herein, ethylene dichloride, cyclohexanone, methyl ethyl ketone, methanol, ethanol, propanol, ethylene glycol monomethyl ether, 1-methoxy-2-propanol, 2-methoxyethyl acetate, 1-methoxy-2-propyl acetate, dimethoxyethane, methyl lactate, ethyl lactate, N,N-dimethyl acetamide, N,N-dimethyl formamide, tetramethylurea, N-methylpyrrolidone, dimethyl sulfoxide, sulfolane, γ-butyrol lactone, toluene, water or the like may be mentioned, without being limited to these. These solvents may be used either alone or in mixtures. The concentration of the solids in the coating liquid is preferably 1 to 50% by mass.

The photosensitive-thermosensitive layer of the invention can be also formed by preparing a plurality of coating liquids in which the same or different components are dispersed or dissolved in the same or different solvents, and repeating the coating and drying of the solutions multiple times.

Further, the amount of the photosensitive-thermosensitive layer coating (the solids) on the support as obtained after coating and drying varies depending on the use, but in general it is preferably 0.3 to 3.0 g/m². Within this range, good sensitivity and good film-forming property of the photosensitive-thermosensitive layer may be obtained.

For the method of coating, various methods can be used. For example, bar-coater coating, rotary coating, spray coating, curtain coating, tip coating, air-knife coating, blade coating, roll coating or the like may be mentioned.

(B) Image-Forming Elements of Hydrophobized Precursor System

<Hydrophobized Precursors>

The hydrophobized precursor as used in the invention means a microparticle that can change the hydrophilic photosensitive-thermosensitive layer to be hydrophobic when heat is applied. This microparticle is preferably at least one microparticle selected from a thermoplastic polymer microparticle and a thermoreactive polymer microparticle. Also, it can be a microcapsule encapsulating a compound having a thermoreactive group.

For the thermoplastic polymer microparticles used in the photosensitive-thermosensitive layer of the invention, mention may be made preferably of the thermoplastic polymer microparticles as described in Research Disclosure No. 33303 of January 1992, JP-A Nos. 9-123387, 9-131850, 9-171249 and 9-171250, and EP No. 931647. Specific examples of the polymer constituting such polymer microparticles may include the homopolymers or copolymers of monomers such as ethylene, styrene, vinyl chloride, methyl acrylate, ethyl acrylate, methyl methacrylate, ethyl methacrylate, vinylidene chloride, acrylonitrile, vinyl carbazole or the like, or mixtures thereof. More preferred among these are polystyrene and polymethyl methacrylate.

The average particle size of the thermoplastic polymer microparticles used in the invention is preferably 0.01 to 2.0 μm. As the method of synthesizing such thermoplastic polymer microparticles, mention may be made of, in addition to an emulsion polymerization technique and a suspension polymerization technique, a method of dissolving the compounds in a water-insoluble organic solvent, mixing and emulsifying the resulting solution with an aqueous solution containing a dispersant, and then solidifying into microparticles while evaporating the organic solvent with application of heat (dissolution-dispersion technique).

For the thermoreactive polymer microparticles used in the invention, mention may be made of thermocurable polymer microparticles, and polymer microparticles having a thermoreactive group.

As the thermocurable polymer, mention may be made of resins having the phenolic backbone, urea-based resins (for example, those formed by resinification of urea or a urea derivative such as methoxymethylated urea using an aldehyde such as formaldehyde), melamine-based resins (for example, those formed by resinification of melamine or its derivative using an aldehyde such as formaldehyde), alkyd resins, unsaturated polyester resins, polyurethane resins, epoxy resins or the like. Among these, the resins having the phenolic backbone, melamine resins, urea resins and epoxy resins are particularly preferred.

Preferred resins having the phenolic backbone may include, for example, phenolic resins formed by resinification of phenol, cresol or the like using an aldehyde such as formaldehyde, hydroxystyrene resins, and the polymers and copolymers of methacrylamide or acrylamide or methacrylate or acrylate having the phenolic backbone such as N-(p-hydroxyphenyl) methacrylamide, p-hydroxyphenyl methacrylate or the like.

The average particle size of the thermocurable polymer microparticles used in the invention is preferably 0.01 to 2.0 μm. Such thermocurable polymer microparticles can be easily obtained by the dissolution-dispersion technique, but it is also possible to carry out formation of microparticles upon the synthesis of the thermocurable polymer. However, the invention is not intended to be limited to these techniques.

As the thermoreactive group for the polymer microparticles with a thermoreactive group used in the invention, it can be any functional group undergoing any reaction as long as a chemical bond will be formed; however, mention may be made preferably of an ethylenically unsaturated group implementing radical polymerization (for example, an acryloyl group, a methacryloyl group, a vinyl group, an aryl group, etc.), a cationic polyermizable group (for example, a vinyl group, a vinyloxy group, etc.), an isocyanate group or its block form implementing addition reaction, an epoxy group, a vinyloxy group and a functional group having an activated hydrogen atom as the counterpart of the foregoing groups (for example, an amino group, a hydroxyl group, a carboxyl group, etc.), acid anhydride implementing bonding reaction and its couterpart amino group or hydroxyl group, or the like.

The introduction of these functional groups into the polymer microparticles may be carried out during polymerization, or after polymerization, using a polymeric reaction.

In the case of introducing during polymerization, it is preferable to carry out emulsion polymerization or suspension polymerization of a monomer having such functional group. Specific examples of the monomer having such functional group may include aryl methacrylate, aryl acrylate, vinyl methacrylate, vinyl acrylate, 2-(vinyloxy)ethyl methacrylate, p-vinyloxystyrene, p-{2-(vinyloxy)ethyl}styrene, glycidyl methacrylate, glycidyl acrylate, 2-isocyanate ethyl methacrylate or a block isocyanate derived from alcohol of the former, 2-isocyanate ethyl acrylate or a block isocyanate derived from alcohol of the former, 2-aminoethyl methacrylate, 2-aminoethyl acrylate, 2-hydroxyethyl methacrylate, 2-hydroxyethyl acrylate, acrylic acid, methacrylic acid, maleic anhydride, bifunctional acrylate, bifunctional methacrylate or the like, without being limited to these.

According to the invention, use can be made of copolymers of these monomers with monomers which have no thermoreactive functional group and which are copolymerizable with the foregoing monomers. As the copolymerizable monomer having no thermoreactive group, for example, styrene, alkyl acrylate, alkyl methacrylate, acrylonitrile, vinyl acetate or the like may be mentioned, but such monomer is not limited to these as long as it is a monomer having no thermoreactive group.

In the case of carrying out introduction of a thermoreactive group after polymerization, for example, the polymeric reaction as described in the pamphlet of WO 96/34316 may be mentioned.

Among the polymer microparticles with a thermoreactive group, those coalescing with other polymer microparticles under heat are preferred, and those having hydrophilic surfaces and thus dispersing in water are particularly preferred. It is preferable that the contact angle (water droplet in the air) of the film prepared by coating the polymer microparticles and drying at a temperature lower than the condensation temperature, be smaller than the contact angle (water droplet in the air) of the film prepared by drying at a temperature higher than the condensation temperature. As such, in order to make the surface of the polymer microparticles hydrophilic, a hydrophilic polymer or oligomer such as polyvinyl alcohol, polyethylene glycol or the like, or a hydrophilic low molecular compound may be adsorbed on the surface of the polymer microparticles. However, the techniques of surface hydrophilization are not limited to these.

The condensation temperature of these polymer microparticles having a thermoreactive group is preferably 70° C. or higher, and on consideration of the stability over time, 100° C. or higher is more preferred. The average particle size of the polymer microparticles is preferably 0.01 to 2.0 μm, inter alia, more preferably 0.05 to 2.0 μm, and particularly most preferably 0.1 to 1.0 μm. Within these ranges, good resolution and stability over time can be obtained.

As the thermoreactive group for the microcapsules encapsulating the compound having a thermoreactive group as used in the invention, the thermoreactive groups which are identical with those used in the above-mentioned polymer microparticles having a thermoreactive group may be mentioned to be preferable. Now, the compound having a thermoreactive group will be explained.

As the compound having a radical-polymerizable unsaturation, use can be made preferably of the compounds such as those listed for the radical polymerization-based microcapsules.

As the compound having vinyloxy group preferable for the invention, those compounds as described in JP-A No. 2002-29162 may be mentioned. Specific examples may include tetramethylene glycol divinyl ether, trimethylolpropane trivinyl ether, tetraethylene glycol divinyl ether, penerythritol divinyl ether, pentaerythritol trivinyl ether, pentaerythritol tetravinyl ether, 1,4-bis{2-(vinyloxy)ethyloxy}benzene, 1,2-bis{2-(vinyloxy)ethyloxy}benzene, 1,3-bis{2-(vinyloxy)ethyloxy}benzene, 1,3,5-tris{2-(vinyloxy)ethyloxy}benzene, 4,4′-bis{2-(vinyloxy)ethyloxy}biphenyl, 4,4′-bis(2-(vinyloxy)ethyloxy)diphenyl ether, 4,4′-bis{2-(vinyloxy)ethyloxy}diphenylmethane, 1,4-bis{2-(vinyloxy)ethyloxy}naphthalene, 2,5-bis{2-(vinyloxy)ethyloxy}furan, 2,5-bis{2-(vinyloxy)ethyloxy}thiophen, 2,5-bis{2-(vinyloxy)ethyloxy}imidazole, 2,2-bis[4-{2-(vinyloxy)ethyloxy}phenyl]propane {bis(vinyloxyethyl) ether of bisphenol A}, 2,2-bis{4-(vinyloxymethyloxy)phenyl}propane, 2,2-bis{4-(vinyloxy)phenyl}propane or the like, without being limited to these.

As the compound having epoxy group preferable for the invention, a compound having two or more epoxy groups is preferred, and mention may be made of glycidyl ether compounds obtained by the reaction between a polyhydric alcohol or a polyhydric phenol or the like with epichlorohydrin, or prepolymers thereof, and further the homopolymers or copolymers of glycidyl acrylate or glycidyl methacrylate, or the like.

Specific examples may include propylene glycol diglycidyl ether, tripropylene glycol diglycidyl ether, polypropylene glycol diglycidyl ether, neopentyl glycol diglycidyl ether, trimethylol propane triglycidyl ether, hydrated diglycidyl ether of bisphenol A, hydroquinone diglycidyl ether, resorcinol diglycidyl ether, diglycidyl ether or epichlorohydrin polyadduct of bisphenol A, diglycidyl ether or epichlorohydrin polyadduct of bisphenol F, diglycidyl ether or epichlorohydrin polyadduct of halogenated bisphenol A, diglycidyl ether or epichlorohydrin polyadduct of biphenyl type bisphenol, glycidyl etherification product of novolac resins, or the like, and further the copolymers of methyl methacrylate/glycidyl methacrylate, copolymers of ethyl methacrylate/glycidyl methacrylate or the like.

As the commercial products of the above-mentioned compounds, mention may be made of, for example, Epicoat 1001 (M.W. ca. 900, epoxy equivalent 450 to 500), Epicoat 1002 (M.W. ca. 1600, epoxy equivalent 600 to 700), Epicoat 1004 (M.W. ca. 1060, epoxy equivalent 875 to 975), Epicoat 1007 (M.W. ca. 2900, epoxy equivalent 2000), Epicoat 1009 (M.W. ca. 3750, epoxy equivalent 3000), Epicoat 1010 (M.W. ca. 5500, epoxy equivalent 4000), Epicoat 1100L (epoxy equivalent 4000), Epicoat YX31575 (epoxy equivalent 1200), all of the above manufactured by Japan Epoxy Resin Co., Ltd., and Sumiepoxy ESCN-195×HN, ESCN-195XL, ESCN-195×F manufactured by Sumitomo Chemical Company, Ltd., or the like.

As the isocyanate compound preferable for the invention, tolylene diisocyanate, diphenylmethane diisocyanate, polymethylene polyphenyl polyisocyanate, xylene diisocyanate, naphthalene diisocyanate, cyclohexane phenylene diisocyanate, isophoron diisocyanate, hexamethylene diisocyanate, cyclohexyl diisocyanate, or the compounds obtained by blocking the foregoing compounds with alcohol or amine may be mentioned.

As the amine compound preferable for the invention, ethylene diamine, diethylene triamine, triethylene tetramine, hexamethylene diamine, propylene diamine, polyethylene imine or the like may be mentioned.

As the compound having hydroxyl group preferable for the invention, the compounds having methylol group at the end, polyhydric alcohols such as pentaerythritol, bisphenol, polyphenols or the like may be mentioned.

As the compound having carboxyl group preferable for the invention, mention may be made of aromatic polybasic carboxylic acids such as pyromellitic acid, trimellitic acid, phthalic acid or the like; aliphatic polybasic carboxylic acids such as adipic acid; or the like. As the acid anhydride preferable for the invention, pyromellitic anhydride, benzophenone tetracarboxylic anhydride or the like may be mentioned.

Microencapsulation of the above-mentioned compound having a thermoreactive group can be carried out by any known method described in the explanation for the radical polymerization system.

<Other Components for the Photosensitive-Thermosensitive Layer>

The photosensitive-thermosensitive layer of the invention may contain a hydrophilic resin for the improvement of the capability of the on-board development or the film strength of the photosensitive-thermosensitive layer itself. As such hydrophilic resin, for example, those having a hydrophilic group such as a hydroxyl group, an amino group, a carboxyl group, a phosphoric acid group, a sulfonic acid group, an amide group or the like are preferred. Further, it is preferable for the hydrophilic resin to have a group reactive with the thermoreactive groups contained by the hydrophobized precursor, since crosslinking with the hydrophobized precursor would result in high image strength and high resistance to printing. For example, when the hydrophobized precursor has a vinyloxy group or an epoxy group, the hydrophilic resin preferably has a hydroxyl group, a carboxyl group, a phosphoric acid group, a sulfonic acid group or the like. Inter alia, the hydrophilic resin having a hydroxyl group or a carboxyl group is preferred.

Specific examples of the hydrophilic resin may include gum Arabic, casein, gelatin, starch derivatives, soybean gum, hydroxypropylcellulose, methylcellulose, carboxymethylcellulose and its sodium salt, cellulose acetate, sodium alginate, copolymers of vinyl acetate/maleic acid, copolymers of styrene/maleic acid, polyacrylic acids and their salts, polymethacrylic acids and their salts, homopolymers and copolymers of hydroxyethyl methacrylate, homopolymers and copolymers of hydroxyethyl acrylate, homopolymers and copolymers of hydroxylpropyl methacrylate, homopolymers and copolymers of hydroxylpropyl acrylate, homopolymers and copolymers of hydroxybutyl methacrylate, homopolymers and copolymers of hydroxybutyl acrylate, polyethylene glycols, hydroxypropylene polymers, polyvinyl alcohols, hydrolyzed polyvinyl acetate with the degree of hydrolysis of 60 mol % or more and preferably of 80 mol % or more, polyvinyl formal, polyvinyl pyrrolidone, homopolymers and copolymers of acrylamide, homopolymers and copolymers methacrylamide, homopolymers and copolymers of N-methylol acrylamide, homopolymers and copolymers of 2-acrylamide-2-methyl-1-propanesulfonic acid, homopolymers and copolymers of 2-methacroyloxyethyl phosphonate, or the like.

The amount of the hydrophilic resin to be added to the photosensitive-thermosensitive layer is preferably 20% by mass or less, and more preferably 10% by mass or less.

Furthermore, the hydrophilic resin can be also used as crosslinked to the extent that the unexposed area can be developed on-board on the printing press. As the crosslinking agent, mention may be made of aldehydes such as glyoxal, a melamine formaldehyde resin, a urea formaldehyde resin or the like; methylol compounds such as N-methylol urea or N-methylol melamine, a methylolated polyamide resin or the like; activated vinyl compounds such as divinylsulfone, bis(β-hydroxyethyl sulfonate) or the like; epoxy compounds such as epichlorohydrin or polyethylene glycol glycidyl ether, polyamide, polyamine, epichlorohydrin adducts, a polyamide-epichlorohydrin resin or the like; ester compounds such as monochloroacetic ester, thioglycolic ester or the like; polycarboxylic acids such as polyacrylic acid, copolymers of methylvinyl ether/maleic acid, or the like; inorganic crosslinking agents such as boric acid, titanyl sulfate, Cu, Al, Sn, V, Cr salts, etc., modified polyamide polyimide resins or the like. Other crosslinking media such as ammonium chloride, a silane coupling agent, a titanate coupling agent or the like may be used in combination.

The photosensitive-thermosensitive layer of the invention may contain a reaction promoting agent which initiates or promotes the reaction of the above-mentioned thermoreactive group. As such reaction promoting agent, the above-described photo-acid generator or radical generator for the color changing system, the radical polymerization initiator for the polymerization system or the like may be mentioned favorably.

Said reaction promoting agent can be also used in combination of two or more species. In addition, the addition of the reaction promoting agent to the photosensitive-thermosensitive layer may be either direct addition into the coating liquid for the photosensitive-thermosensitive layer, or addition in the state as contained in the polymer microparticles. The content of the reaction promoting agent in the photosensitive-thermosensitive layer is preferably 0.01 to 20% by mass, and more preferably 0.1 to 10% by mass, with respect to the total solids in the photosensitive-thermosensitive layer. Within these ranges, good effect of reaction initiation or promotion can be obtained without impairing the capability of the on-board development.

In the photosensitive-thermosensitive layer of the hydrophobized precursor system of the invention, a polyfunctional monomer can be added to the matrix of the photosensitive-thermosensitive layer in order to improve the resistance to printing even further. As the polyfunctional monomer, those exemplified as the polymerizable compounds can be used. Preferred monomers among these may include trimethylolpropane triacrylate, pentaerythritol triacrylate or the like.

Furthermore, in the photosensitive-thermosensitive layer of the hydrophobized precursor system of the invention, the additives described in the section <Other components for the photosensitive-thermosensitive layer>for the polymerization-based photosensitive-thermosensitive layer, such as surfactants, polymerization inhibitor, higher fatty acid derivatives, plasticizer, inorganic microparticles, low molecular hydrophilic compounds or the like may be incorporated if necessary.

<Formation of the Photosensitive-Thermosensitive Layer of the Hydrophobized Precursor System>

The photosensitive-thermosensitive layer of the hydrophobized precursor system of the invention is formed by preparing a coating liquid by dispersing or dissolving the above-described respective components as necessary in a solvent and coating and drying the coating liquid on the support, in the same manner as the case of the photosensitive-thermosensitive layer of the radical polymerization system.

The amount of the coating (solids) for the photosensitive-thermosensitive layer obtained after coating and drying on the support may vary depending on the use, but in general it is preferably 0.5 to 5.0 g/m².

It is possible to produce a lithographic printing plate precursor capable of the on-board development using the photosensitive-thermosensitive layer of the hydrophobized precursor system.

Meanwhile, by applying the photosensitive-thermosensitive layer of the hydrophobized precursor system as the “hydrophilic layer having a crosslinked structure” which is sufficiently resistant to printing even under non-exposure, the lithographic printing plate precursor of the invention can be applied to the lithographic printing plate precursor of the non-treatment (non-development) type.

Preferred embodiments of the hydrophilic layer having a crosslinked structure contain at least one of the hydrophilic resin achieved by formation of a crosslinked structure, and the inorganic hydrophilic binding resin formed by sol-gel transition. Among these, the hydrophilic resin will be first explained. Addition of this hydrophilic resin results in good affinity to the hydrophilic components in the emulsion ink and further has an advantage of improving the film strength of the photosensitive-thermosensitive layer itself. As the hydrophilic resin, for example, those having a hydrophilic group such as hydroxyl, carboxyl, hydroxyethyl, hydroxypropyl, amino, aminoethyl, aminopropyl, carboxymethyl or the like are preferred.

Specific examples of the hydrophilic resin may include gum Arabic, casein, gelatin, starch derivatives, carboxymethylcellulose and its sodium salts, cellulose acetate, sodium alginate, copolymers of vinyl acetate-maleic acid, copolymers of styrene-maleic acid, polyacrylic acids and their salts, polymethacrylic acids and their salts, homopolymers and copolymers of hydroxyethyl methacrylate, homopolymers and copolymers of hydroxyethyl acrylate, homopolymers and copolymers of hydroxypropyl methacrylate, homopolymers and copolymers of hydroxypropyl acrylate, homopolymers and copolymers of hydroxybutyl methacrylate, homopolymers and copolymers of hydroxybutyl acrylate, polyethylene glycols, hydroxypropylene polymers, polyvinyl alcohols, and hydrolyzed polyvinyl acetate with the degree of hydrolysis of at least 60 mol %, and at least preferably 80 mol %, polyvinyl formal, polyvinyl butyral, polyvinyl pyrrolidone, homopolymers and copolymers of acrylamide, homopolymers and copolymers of methacrylamide, homopolymers and copolymers of N-methylol acrylamide or the like.

In the case of using said hydrophilic resins in the photosensitive-thermosensitive layer according to the invention, the hydrophilic resins may be used after crosslinking. As the crosslinking agent used to form crosslinked structures, mention may be made of the crosslinking agents mentioned in the above.

In addition, as a preferred embodiment of the photosensitive-thermosensitive layer of the non-treatment (non-development) type, incorporation of the inorganic hydrophilic binding resin formed by sol-gel transition may be mentioned. A preferred sol-gel transition system binding resin is a polymer in which the bonding group from a polyvalent element forms a network-shaped structure, that is, a three-dimensional crosslinked structure via oxygen atoms, and at the same time, a polyvalent metal also has a non-bonded hydroxyl group or an alkoxy group, these being co-present in a resin-like structure. This is in the sol state in a step abundant with alkoxy group or hydroxyl group, and as dehydration condensation proceeds, the network-shaped resin structure is fortified. The polyvalent bonding element of the compound which has alkoxy group or hydroxyl group for sol-gel transition includes aluminum, silicon, titanium and zirconium, and these all can be used in the invention. Among these, more preferable is the sol-gel transition system using silicon, and particularly preferred is the system containing a silane compound having at least one silanol group and capable of sol-gel transition. Hereinbelow, the sol-gel transition system using silicon will be explained. The sol-gel transition systems using aluminum, titanium and zirconium can be implemented with the below-described silicone with the respective elements.

The sol-gel transition system binding resin is preferably a resin having a siloxane bond and a silanol group. For the photosensitive-thermosensitive layer of the invention, a sol-based coating liquid containing a compound having at least one silanol group is used, condensation of the silanol group proceeds during the coating and drying process to lead to gelling, and the compound may be contained by the process of formation of the siloxane skeletal structure.

Further, the photosensitive-thermosensitive layer containing the sol-gel transition system binding resin is intended for the improvement of the physical performance such as film strength, film flexibility or the like, or the improvement of the coating property, and thus it is possible to use it in combination with the above-mentioned hydrophilic resins or crosslinking agents.

The siloxane resin forming a gel structure is represented by the following general formula (II), and the silane compound having at least one silanol group is represented by the following general formula (III). Further, the substance system added to the photosensitive-thermosensitive layer is not necessarily the silane compound of the general formula (III) alone, and may be generally an oligomer to which the silane compound partially bonded, or a mixture of the silane compound of the general formula (III) and the oligomer.

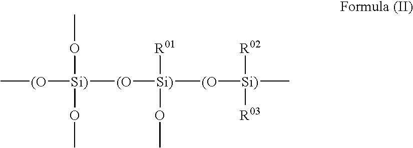

The siloxane resin of the general formula (II) is formed by sol-gel transition in a dispersion containing at least one silane compound represented by the general formula (III). Herein, at least one of R⁰¹-R⁰³ in the general formula (II) represents a hydroxyl group, and the others represent an organic residue selected from the symbols R⁰ and Y in the general formula (III).
(R⁰)ₙSi(Y)₄₋ₙ Formula (III)

Here, R⁰ represents a hydroxyl group, a hydrocarbon group or a heterocyclic group. Y represents a hydrogen atom, a halogen atom, —OR¹, —OCOR² or —N(R³)(R⁴). R¹ and R² each represent a hydrocarbon group, and R³ and R⁴, which may be identical or different, represent a hydrocarbon group or a hydrogen atom. n represents 0, 1, 2 or 3.

The hydrocarbon group or the heterocyclic group of R⁰ means, for example, an optionally substituted, straight-chained or branched C₁₋₁₂ alkyl group (for example, a methyl group, an ethyl group, a propyl group, a butyl group, a pentyl group, a hexyl group, a heptyl group, an octyl group, a nonyl group, a decyl group, a dodecyl group etc.; the groups substituted on the foregoing groups may include a halogen atom (chlorine atom, fluorine atom, bromine atom), a hydroxyl group, a thiol group, a carboxyl group, a sulfa group, a cyano group, an epoxy group, —OR′ group (wherein R′ represents a methyl group, an ethyl group, a propyl group, a butyl group, a heptyl group, a hexyl group, an octyl group, a decyl group, a propenyl group, a butenyl group, a hexenyl group, an octenyl group, a 2-hydroxyethyl group, a 3-chloropropyl group, a 2-cyanoethyl group, a N,N-dimethylaminoethyl group, a 2-bromoethyl group, a 2-(2-methoxyethyl) oxyethyl group, a 2-methoxycarbonylethyl group, a 3-carboxyethyl group, a 3-carboxypropyl group, a benzyl group or the like);
a —OCOR″ group (wherein R″ represents the same meanings as R′ as described above), a —COOR″ group, a —COR″ group, a —N(R′″)(R′″) group (wherein R′″ represents a hydrogen atom or the same meanings as R′ as described above, and may be identical with or different from each other), a —NHCONHR″ group, a —NHCOOR″ group, a —Si(R″)₃ group, a —CONHR″ group or the like. These substituents may be plurally substituted on the alkyl group. An optionally substituted, straight-chained or branched C₂₋₁₂ alkenyl group (for example, a vinyl group, a propenyl group, a butenyl group, a pentenyl group, a hexenyl group, an octenyl group, a decenyl group, a dodecenyl group, etc.; the groups substituted on the foregoing groups may include those identical with the substituents for the alkyl group), an optionally substituted C₇₋₁₄ aralkyl group (for example, a benzyl group, a phenethyl group, 3-phenylpropyl group, a naphthylmethyl group 2-naphthylethyl group, etc.; the groups substituted on the foregoing groups may be identical with the substituents for the alkyl group and may be plurally substituted), an optionally substituted C₅₋₁₀ alicyclic group (for example, a cyclopentyl group, a cyclohexyl group, a 2-cyclohexylethyl group, a norbornyl group, an adamantyl group, etc.; the groups substituted on the foregoing groups may be identical with the substituents for the alkyl group and may be plurally substituted), an optionally substituted C₆₋₁₂ aryl group (for example, a phenyl group, a naphthyl group; the groups substituted on the foregoing groups may be identical with the substituents for the alkyl group and may be plurally substituted), an optionally cyclic condensed heterocyclic group containing at least one atom selected from nitrogen atom, oxygen atom and sulfur atom (for example, substituents such as a pyrane ring, a furan ring, a thiophen ring, a morpholine ring, a pyrrole ring, a thiazole ring, an oxazole ring, a pyridine ring, a piperidine ring, a pyrrolidone ring, a benzothiazole ring, a benzoxazole ring, a quinoline ring, a tetrahydrofuran ring, or the like may be incorporated. As the substituents, the same meanings as the substituents for the alkyl group may be mentioned and may also plurally substituted) can be presented.

As the substituents for the —OR¹ group, the —OCOR² group or the —N(R³)(R⁴) group of Y in the general formula (III), for example, the following substituents may be presented. For the —OR¹ group, R¹ represents an optionally substituted C₁₋₁₀ aliphatic group (for example, a methyl group, an ethyl group, a propyl group, a butyl group, a heptyl group, a hexyl group, a pentyl group, an octyl group, a nonyl group, a decyl group, a propenyl group, a butenyl group, a heptenyl group, a hexenyl group, an octenyl group, a decenyl group, a 2-hydroxyethyl group, a 2-hydroxypropyl group, a 2-methoxyethyl group, a 2-(2-methoxyethyl) oxyethyl group, a 2-(N,N-dimethylamine)ethyl group, a 2-methoxypropyl group, a 2-cyanoethyl group, a 3-methyloxypropyl group, a 2-chloroethyl group, a cyclohexyl group, a cyclopentyl group, a cyclooctyl group, a chlorocyclohexyl group, a methoxycyclohexyl group, a benzyl group, a phenethyl group, a dimethoxybenzyl group, a methylbenzyl group, a bromobenzyl group or the like).

For the —OCOR² group, R² represents an aliphatic group which is the same as for R¹, or an optionally substituted C₆₋₁₂ aromatic group (the aromatic group may be the same as that illustrated above for the aryl group for R). Further, for —N(R³)(R⁴) group, R³ and R⁴ may be identical with and different from each other and each present a hydrogen atom or an optionally substituted C₁₋₁₀ aliphatic group (for example, the same matter as those for R¹ in the —OR¹ group may be mentioned). More preferably, the sum of the number of carbon atoms in R³ and R⁴ is not more than 16. As specific examples of the silane compounds represented by the general formula (III), the following may be mentioned, without being limited to these.

Mention may be made of tetrachlorosilane, tetramethoxysilane, tetraethoxysilane, tetraisopropoxysilane, tetra-n-propylsilane, methyltrichlorosilane, methyltrimethoxysilane, methyltriethoxysilane, ethyltrichlorosilane, ethyltrimethoxysilane, ethyltriethoxysilane, n-propyltrichlorosilane, n-propyltrimethoxysilane, n-hexyltrimethoxysilane, n-decyltrimethoxysilane, phenyltrichlorosilane, phenyltrimethoxysilane, dimethoxyditriethoxysilane, dimethyldichlorosilane, dimethyldimethoxysilane, diphenyldimethoxysilane, phenylmethyl dimethoxysilane, triethoxyhydrosilane, trimethoxyhydrosilane, vinyltrichlorosilane, vinyltrimethoxysilane, trifluoropropyl trimethoxysilane, γ-glycidoxypropylmethyl dimethoxysilane, γ-glycidoxypropylmethyl diethoxysilane, γ-glycidoxypropyl triethoxysilane, γ-methacryloxypropyl trimethoxysilane, γ-aminopropylmethyl dimethoxysilane, γ-aminopropyltriethoxysilane, γ-mercaptopropylmethyl dimethoxysilane, γ-mercaptopropyl trimethoxysilane, γ-mercaptopropyl triethoxysilane, β-(3,4-epoxycyclohexyl)ethyltrimethoxysilane or the like.

In the photosensitive-thermosensitive layer of the invention, together with the silane compound of the general formula (III), metal compounds such as Ti, Zn, Sn, Zr, Al or the like, which are capable of forming a film by binding to the resin upon sol-gel transition, can be used in combination. As such metal compound used, for example, Ti(OR″)₄, TiCl₄, Zn(OR″)₂, Zn(CH₃COCHCOCH₃)₂, Sn(OR″)₄, Sn(CH₃COCHCOCH₃)₄, Sn(OCOR″)₄, SnCl₄, Zr(OR″)₄, Zr(CH₃COCHCOCH₃)₄, (NH₄)₂ZrO(CO₃)₂, Al(OR″)₃, Al(CH₃COCHCOCH₃)₃ or the like may be mentioned, wherein R″ represents a methyl group, an ethyl group, a propyl group, a butyl group, a pentyl group, a hexyl group or the like.

Further, in order to promote hydrolysis and polycondensation reactions of the compound represented by the general formula (III) as well as the above-mentioned metal compounds to be combined, it is preferable to use an acidic catalyst or a basic catalyst in combination. The catalyst is used as such as an acidic or basic compound, or in the form of a solution dissolved in a solvent such as water or alcohol (hereinafter, respectively referred to as an acidic catalyst and a basic catalyst). The concentration thereof is not particularly limited, but in the case of high concentration, there is a tendency for the rates of hydrolysis and polycondensation being increased. Yet, when a basic catalyst of high concentration is used, since precipitation may occur in the sol solution, the concentration of the basic catalyst is preferably 1 N (in terms of concentration in an aqueous solution) or less.

Specific examples of the acidic catalyst may include hydrohalide acids such as hydrochloric acid, nitric acid, sulfuric acid, sulfurous acid, hydrogen sulfide, perchloric acid, hydrogen peroxide, carbonic acid, carboxylic acids such as formic acid, acetic acid or the like, sulfonic acids such as benzenesulfonic acid or the like. Specific examples of the basic catalyst may include ammoniacal bases such as aqueous ammonia, amines such as ethylamine, aniline or the like, without being limited to these.

The photosensitive-thermosensitive layer utilizing the sol-gel technique as described above is particularly preferable as the constitution for the photosensitive-thermosensitive layer related to the invention. Further details of the sol-gel technique are described in Sumio Sakuhana, “Science of the Sol-Gel Process”, Agune-Shofusha(1988), Hirajima Ken, “Functional Thin Film-Forming Techniques by Up-To-Date Sol-Gel”, Comprehensive Technology Center(1992) or the like.

The amount of addition of the hydrophilic resin in the photosensitive-thermosensitive layer in the crosslinked structure is preferably 5 to 70% by mass, and more preferably 5 to 50% by mass, of the solids in the photosensitive-thermosensitive layer.

[Support]

The support used in the lithographic printing plate precursor of the invention is not particularly limited as long as it is a hydrophilic support, and it may be a plate-shaped object which is dimensionally stable. For example, paper, paper laminated with plastic (for example, polyethylene, polypropylene, polystyrene, etc.), metal plate (for example, aluminum, zinc, copper, etc.), plastic film (for example, cellulose diacetate, cellulose triacetate, cellulose propionate, cellulose butyrate, cellulose acetate butyrate, cellulose nitrate, polyethylene terephthalate, polyethylene, polystyrene, polypropylene, polycarbonate, polyvinylacetal, etc.), paper or plastic film with the above-mentioned metal being laminated or vapor-deposited thereon, or the like. As the preferred support, a polyester film and an aluminum plate may be mentioned. Among these, the relatively inexpensive aluminum plate having good dimensional stability is preferred.

The aluminum plate is a pure aluminum plate, a metal plate containing aluminum as the main component and trace amounts of other elements, or an aluminum alloy thin film having a plastic laminated thereon. Other elements contained in the aluminum alloy may include silicon, iron, manganese, copper, magnesium, chromium, zinc, bismuth, nickel, titanium or the like. The content of other elements in the alloy is preferably 10% by mass or less. Although a pure aluminum plate is preferred in the invention, since it is difficult to produce perfectly pure aluminum by the current refinery technology, one containing trace amounts of other elements will be appropriate. The aluminum plate is not characterized by the composition, and thus a plate of any known material for general use can be appropriately used.

The thickness of the support is preferably 0.1 to 0.6 mm, more preferably 0.15 to 0.4 mm, and even more preferably 0.2 to 0.3 mm.

Prior to the use, the aluminum plate is preferably subjected to surface treatment such as surface roughening, formation of hydrophilic film or the like. Such surface treatment facilitates the improvement of hydrophilicity and assurance of close adherence between the photosensitive-thermosensitive layer and the support. Before surface-roughening the aluminum plate, if desired, degreasing by surfactants, organic solvents, alkaline aqueous solutions or the like is carried out to remove the oil for rolling on the surface.

<Surface-Roughening Treatment>

The surface-roughening treatment of the aluminum plate surface may be achieved by various methods, and for example, mechanical surface-roughening treatment, electrochemical surface-roughening treatment (surface-roughening by dissolve the surface electrochemically), chemical surface-roughening treatment (surface-roughening by selectively dissolving the surface chemically) or the like may be mentioned.

As the mechanical surface-roughening method, any known techniques such as ball polishing, brush polishing, blast polishing, buff polishing or the like can be used.

As the electrochemical surface-roughening method, for example, a method of surface-roughening by means of alternative current or direct current in an electrolytic solution containing an acid such as hydrochloric acid, nitric acid or the like may be mentioned. Further, the method of using a mixed acid as described in JP-A No. 54-63902 can be also mentioned.

<Formation of Hydrophilic Film>

The aluminum plate thus subjected to the surface-roughening treatment and other treatments as necessary is again subjected to a treatment to build thereon a hydrophilic film of low heat conductivity. The hydrophilic film has a heat conductivity in the direction of film depth of 0.05 W/mK or more, preferably 0.08 W/mK or more, and 0.5 W/mK or less, preferably 0.3 W/mK or less, even more preferably 0.2 W/mK or less. When the heat conductivity in the depth direction is 0.05 W/mK to 0.5 W/mK, diffusion of the heat generated in the photosensitive-thermosensitive layer upon exposure to laser light to the support can be suppressed. As a result, when the lithographic printing plate precursor of the invention is used as the on-board development type or the non-treatment type, the heat generated upon exposure to laser light can be utilized effectively, and thus the sensitivity is enhanced, and sufficient formation of images to be printed and images to be burned can be achieved.

Hereinafter, an explanation will be given on the heat conductivity in the film depth direction of the hydrophilic film as specified in the invention. For the method of measuring the heat conductivity of thin film, various methods have been reported hitherto. In 1986, Ono et al. reported the measurement of the heat conductivity in the plane direction of thin film using a thermograph. Further, there are reports on the attempt to apply the method of heating by alternating current onto the measurement of the thermal properties of thin film. History of the method of heating by alternating current may be traced up to a report in 1863, but a variety of measuring methods have been suggested owing to the recent development of the methods of heating by laser in combination with the Fourier transformation. An apparatus making use of the laser Angstrom technique is in fact commercially available. These methods all determine the heat conductivity in the plane direction (inner surface direction) of a thin film.

However, on consideration of the heat conductivity of thin film, rather the heat diffusion in the depth direction is a more important factor.

As often reported, the heat conductivity of thin film is not said to be isotropic, and especially for the invention, direct measurement of the heat conductivity in the thickness direction is very important. From this point of view, as an attempt to measure the thermal properties in the direction of film thickness in the thin film, a method of using the thermocomparator as described in Lambropoulos, J. Appl. Phys., 66(9)(Nov. 1, 1989) and Henager et al., APPLIED OPTICS, Vol. 32, No. 1(Jan. 1, 1993) have been reported. Moreover, a method of measuring the heat diffusivity in the polymer thin film by temperature wave thermal analysis with application of Fourier analysis has been recently reported by Hashimoto et al. (Netsu Sokutei, 27(3) (2000)).

The heat conductivity in the film depth direction of the hydrophilic film as specified in the invention is measured by the above-mentioned method of using a thermocomparator. This method will be explained specifically below. The fundamental principle of this method is described in detail in the articles of Lambropoulos et al. and of Henager et al. as described earlier. In the invention, measurement was performed using the thermocomparator shown in FIG. 3 in JP-A No. 2003-103951, according to the method described in the same publication.

The relationship between the respective temperatures and the heat conductivity of the film is as shown in Equation (1) below:

$$[ Equation 1 ]$$

$$\frac{( {T}_{r} - {T}_{b} )}{( {T}_{r} - {T}_{t} )} = ( \frac{4 {K}_{1} {r}_{1}}{{K}_{tf} {A}_{3}} ) t + ( 1 + ( \frac{4 {K}_{1} {r}_{1}}{{K}_{2} {A}_{2}} ) {t}_{2} ( \frac{{K}_{1} {r}_{1}}{{K}_{1} {r}_{1}} ) ) \qquad ( 1 )$$

wherein the symbols in the above Equation (1) are as follows:

Tₜ: tip end temperature, T_{b}: heat sink temperature, Tᵣ: reserver temperature, K_{tf}: heat conductivity of the film, K₁: heat conductivity of the reserver, K₂: heat conductivity of the tip (in the case of oxygen-free copper, 400 W/mK), K₄: heat conductivity of a metal substrate (in the case of not having a film), r₁: the radius of curvature at the tip end, A₂: contact area between the reserver and the tip, A₃: contact area between the tip and the film, t: film thickness, t₂: contact thickness (≈0).

By measuring each temperature (Tₜ, T_{b} and Tᵣ) while varying the film thickness (t) and plotting, the gradient of Equation (1) and subsequently the heat conductivity of the film (K_{tf}) can be obtained. That is, this gradient is a value determined by the heat conductivity of the reserver (K₁), the radius of curvature at the tip end (r₁), the heat conductivity of the film (K_{tf}) and the contact area between the tip and the film (A₃), as obvious from Equation (1), and K₁, r₁ and A₃ are already known values. Thus, from this gradient, the value of K_{tf} can be obtained.

The inventors obtained the heat conductivity of the hydrophilic film (the anodic oxidation film, Al₂O₃) constructed on an aluminum substrate using the above-described method of measurement. While varying the film thickness, the temperatures were measured, and the resulting heat conductivity of Al₂O₃ obtained from the gradient of the graph was 0.69 W/mK. This shows good correlation with the results of the study by Lambropoulos et al. as described above. Further, this result also shows that the thermal property value of thin film is different from the bulk thermal property value (the bulk heat conductivity of Al₂O₃ is 28 W/mK).

In the hydrophilic film of the lithographic printing plate precursor of the invention, it is advantageous to use the above-mentioned method for the measurement of the heat conductivity along the film thickness, since it is possible to obtain uniform results even with respect to the roughened surfaces of the lithographic printing plate, by taking the tip end as a minute one and by maintaining the pressure load constant. The values of the heat conductivity are preferably determined as the average of a plurality of different points, for example, five points, measured on the sample.

The film thickness of the hydrophilic film is preferably 0.1 μm or more, more preferably 0.3 μm or more, and particularly preferably 0.6 μm or more, in the aspects of the anti-damaging property and the resistance to printing. Furthermore, in the aspect of the production costs, it is preferable, upon consideration of the requirement of enormous energy to construct a thick film, that the film thickness be 5 μm or less, more preferably no more than 3 μm, and particularly preferably 2 μm r less.

The hydrophilic film of the invention preferably has a density of 1000 to 3200 kg/m³, in the aspects of the effect on the thermal insulation, film strength, and anti-contamination during printing.

For the method of measuring density, it can be calculated, for example, from the mass measurement according to the Mason's method (the method of weighing the anodic oxidation film by dissolution in a mixed solution of chromic acid/phosphoric acid), and from the film thickness measured by SEM observation of the cross-section, using the following equation:
Density (kg/m³)=(mass of the hydrophilic film per unit area/film thickness)

As the method of constructing the hydrophilic film, anodic oxidation, vapor deposition, a CVD process, sol-gel process, spectering, ion-plating, diffusion technique or the like may be appropriately used, without being particularly limited. Further, a method of coating a solution contained hollow particles mixed in a hydrophilic resin or a sol-gel solution may be also used.

Among these, it is preferable to use the treatment of producing an oxide by anodic oxidation, that is, to use the anodic oxidation treatment. The anodic oxidation treatment can be carried out by any method conventionally used in the art. Specifically, in an aqueous solution or a non-aqueous solution containing sulfuric acid, phosphoric acid, chromic acid, oxalic acid, sulfamic acid, benzenesulfonic acid or the like, alone or in combination of two or more species, direct current or alternating current can be passed through an aluminum plate to form an anodic oxidation film, as a hydrophilic film, on the surface of the aluminum plate. Since the conditions for the anodic oxidation treatment often vary with the electrolytic solution used, they cannot be fixed, but the following conditions will be suitable: in general, concentration of electrolytic solution 1 to 80% by mass, liquid temperature 5 to 70° C., current density 0.5 to 60 A/dm², voltage 1 to 200 V, and time for electrolysis 1 to 1000 seconds. Among these anodic oxidation treatment methods, preferred are the method of anodizing with high current density in a sulfuric acid electrolytic solution as described in GB No. 1,412,768, and the method of anodizing by using phosphoric acid for the electrolytic bath as described in U.S. Pat. No. 3,511,661. Further, it is also possible to carry out multiple anodic oxidation processes by anodizing in sulfuric acid and again anodizing in phosphoric acid.

The anodic oxidation film according to the invention is preferably 0.1 g/m² or more, more preferably 0.3 g/m² or more, particularly preferably 2 g/m² or more, and even more preferably 3.2 g/m² or more in view of uneasy damage and press life. Further, upon consideration of the requirement of enormous energy to construct a thick film, it is preferably 100 g/m² or less, more preferably 40 g/m² or less, and particularly preferably 20 g/m² or less.

The anodic oxidation film has fine recesses, also called as micropores, formed on the surface of the film as evenly distributed. The density of the micropores existing in the anodic oxidation film can be controlled by selecting the treatment conditions appropriately. By increasing the micropore density, the heat conductivity along the film depth direction of the anodic oxidation film can be adjusted to 0.05 to 0.5 W/mK. Further, the size of the micropores can be adjusted by selecting the treatment conditions appropriately. By increasing the size of the micropores, the heat conductivity along the film depth o the anodic oxidation film can be adjusted to 0.05 to 0.5 W/mK. In addition, the size of the micropores can be adjusted by selecting the treatment conditions appropriately. By increasing the size of the micropores, the heat conductivity along the film depth direction of the anodic oxidation film can be adjusted to 0.05 to 0.5 W/mK.

Under the purpose of reducing the heat conductivity in the invention, it is preferable to perform the pore-widening treatment of increasing the pore size of the micropores after the anodic oxidation treatment. This pore-widening treatment is to dissolve the anodic oxidation film and to increase the pore size of the micropores by immersing the aluminum substrate with the anodic oxidation film formed thereon in an aqueous acid solution or in an aqueous alkali solution. The pore-widening treatment is achieved such that the amount of dissolution of the anodic oxidation film is preferably 0.01 to 20 g/m², more preferably 0.1 to 5 g/m², and particularly preferably 0.2 to 4 g/m².

When an aqueous acid solution is used in the pore-widening treatment, it is preferable to use an aqueous solution of an inorganic acid such as sulfuric acid, phosphoric acid, nitric acid, hydrochloric acid or the like as well as mixtures thereof. The concentration of the aqueous acid solution is preferably 10 to 1000 g/L, and more preferably 20 to 500 g/L. The temperature of the aqueous acid solution is preferably 10 to 90° C., and more preferably 30 to 70° C. The time for immersion into the aqueous acid solution is preferably 1 to 300 seconds, and more preferably 2 to 100 seconds. On the other hand, when an aqueous alkali solution is used in the pore-widening treatment, it is preferably to use an aqueous solution of at least one alkali selected from the group formed by sodium hydroxide, potassium hydroxide and lithium hydroxide. The pH of the aqueous alkali solution is preferably 10 to 13, and more preferably 11.5 to 13.0. The temperature of the aqueous alkali solution is preferably 10 to 90° C., and more preferably 30 to 50° C. The time for immersion into the aqueous alkali solution is preferably 1 to 500 seconds, and more preferably 2 to 100 seconds. However, since excessive enlargement of the size of the micropores at the outermost surface leads to deterioration of the contamination performance during printing, the size of the micropores at the outermost surface is preferably 40 nm or less, more preferably 20 nm or less, and most preferably 10 nm or less. Then, the heat-insulating property and the contamination performance can be satisfied together. In a more preferably form of the anodic oxidation film, the size of the micropores at the surface is 0 to 40 nm, and the size of the internal micropores is 20 to 300 nm. For example, it is known that when the same type of the electrolytic solution is used, the pore diameter of the pores produced by electrolysis is directly proportional to the electrolytic voltage during electrolysis. By using this property to gradually elevate the electrolytic voltage, a method of producing wider pores as approaching the bottom. In addition, it is also known that when the type of the electrolytic solution is changed, the pore diameter changes along, and the pore diameter increases with the order of sulfuric acid, oxalic acid and phosphoric acid. Therefore, a method of anodizing using sulfuric acid in the electrolytic solution at a first step and then using phosphoric acid at a second step may be used. Further, pore-sealing treatment as mentioned later, may be carried out on the support for the lithographic printing plate obtained by subjecting it to the anodic oxidation treatment and/or pore-widening treatment.

Further, the hydrophilic film may be also an inorganic film constructed by the techniques of spectering, a CVD process or the like, in addition to the anodic oxidation film as described earlier. As the compound constituting such inorganic film, for example, oxides, nitrides, suicides, borides and carbides may be mentioned. Further, the inorganic film may be composed of a single compound or a mixture of compounds. As the compound constituting the inorganic film, mention may be made specifically of aluminum oxide, silicon oxide, titanium oxide, zirconium oxide, hafnium oxide, vanadium oxide, niobium oxide, tantalum oxide, molybdenum oxide, tungsten oxide, chromium oxide; aluminum nitride, silicon nitride, titanium nitride, zirconium nitride, hafnium nitride, vanadium nitride, niobium nitride, tantalum nitride, molybdenum nitride, tungsten nitride, chromium nitride, silicon nitride, boron nitride; titanium silicide, zirconium silicide, hafnium silicide, vanadium silicide, niobium silicide, tantalum silicide, molybdenum silicide, tungsten silicide, chromium silicide; titanium boride, zirconium boride, hafnium boride, vanadium boride, niobium boride, tantalum boride, molybdenum boride, tungsten boride, chromium boride; aluminum carbide, silicon carbide, titanium carbide, zirconium carbide, hafnium carbide, vanadium carbide, niobium carbide, tantalum carbide, molybdenum carbide, tungsten carbide, chromium carbide or the like.

<Pore-Sealing Treatment>

According to the invention, the support for the lithographic printing plate of the invention obtained by forming a hydrophilic film thereon, as described above, may be subjected to the pore-sealing treatment. The pore-sealing treatment used in the invention may be exemplified by the pore-sealing treatment to the anodic oxidation film by pressurized steam or hot water as described in JP-A Nos. 4-176690 and 11-301135. Also, use may be made of known methods such as silicate treatment, aqueous dichromate solution treatment, nitrite treatment, ammonium acetate treatment, electrodeposition sealing treatment, triethanolamine treatment, barium carbide treatment, treatment with hot water containing trace amount of phosphate, or the like. Regarding the pore-sealing treated film, different pore-sealed film may be formed depending on the method of pore-sealing treatment such that, for example, in the case of electrodeposition sealing treatment, the sealed film is formed from the bottom part of the pores, whereas in the case of steam sealing treatment, the sealed film is formed from the upper part of the pores. In addition to these, there may be mentioned of treatment of immersion in a solution, spray treatment, coating treatment, vapor deposition treatment, spectering, ion-plating, thermal spraying, electroplating and the like, without being limited to these. Particularly preferred among these is the pore-sealing treatment of using particles with an average particle size of 8 to 800 nm, as described in JP-A No. 2002-214764.

The pore-sealing treatment using particles is carried out using particles with an average particle size of 8 to 800 nm, preferably with an average particle size of 10 to 500 nm, and more preferably with an average particle size of 10 to 150 nm. Within these ranges, the risk that particles would go inside of the micropores present in the hydrophilic film is reduced, the effect of high sensitization level can be sufficiently obtained, and sufficient close adherence is achieved between the hydrophilic film and the photosensitive-thermosensitive layer, thus resulting in excellent resistance to printing. The thickness of the particle layer is preferably 8 to 800 nm, and more preferably 10 to 500 nm.

The particles used in the invention have a heat conductivity of preferably 60 W/mK or less, more preferably 40 W/mK or less, and particularly preferably 0.3 to 10 W/mK or less. When the heat conductivity is 60 W/mK or less, sufficient inhibition of heat diffusion at the aluminum substrate is achieved, and thus the effect of high sensitization level can be sufficiently obtained.

As the method of constructing the particle layer, for example, mention may be made of the treatment of immersion in a solution, spray treatment, coating treatment, electrolysis treatment, vapor deposition treatment, spectering, ion-plating, thermal spraying, electroplating and the like, without particularly limited to these.

The electrolysis treatment may be done by using direct current or alternating current. The waveform of the alternating current used in this electrolysis treatment may be the sine wave, the rectangular wave, the triangular wave, the trapezoidal wave or the like. Further, the frequency of the alternating current is preferably 30 to 200 Hz, and more preferably 40 to 120 Hz, from the viewpoint of the production costs for the power supply apparatus. When the trapezoidal wave is used for the waveform of alternating current, the time taken by the current to reach from 0 to the peak value, tp, is preferably 0.1 to 2 msec, and more preferably 0.3 to 1.5 msec. When tp is less than 0.1 msec, the impedance of the power supply circuit would have an effect such as to require a large current voltage at the initiation of the current waveform and to increase the installing costs for the power supply.

As the hydrophilic particles, it is preferable to use Al₂O₃, TiO₂, SiO₂ and ZrO₂, either alone or in combination of two or more species. The electrolytic solution can be obtained, for example, by suspending the hydrophilic particles in water or the like such that the content thereof is 0.01 to 20% by mass with respect to the solution. Since the electrolytic solution works by making the electric charges to be either positive or negative, the pH of the solution can be adjusted, for example, by adding sulfuric acid or the like. The electrolytic treatment is performed, for example, by using direct current and the above-mentioned electrolytic solution, and using an aluminum plate as the cathode, under the conditions of a voltage of 10 to 200 V and a time of 1 to 600 seconds. According to this method, the openings of the micropores present in the anodic oxidation film can be easily sealed, with the inside thereof remained empty.

In addition, for a further method of pore-sealing treatment, mention may be made of a method of constructing, by coating, a layer consisting of a compound having at least one amino group and at least one selected from the group of a carboxyl group and a salt thereof, and a sulfo group and a salt thereof as described in JP-A No. 60-149491; a layer consisting of a compound selected from compounds having at least one amino group and at least one hydroxyl group and salts thereof as described in JP-A No. 60-232998; a layer containing a phosphoric acid salt as described in JP-A No. 62-19494; a layer consisting of a polymeric compound having as the repeating unit, at least one monomer unit having sulfo group in the molecule as described in JP-A No. 59-101651; or the like.

Further, mention may be also made of a method of constructing a layer of a compound selected from carboxymethylcellulose; dextrin; gum Arabic; phosphonic acids having an amino group such as 2-aminoethyl phosphonic acid or the like; organic phosphonic acids such as optionally substituted phenyl phosphonic acid, naphthyl phosphonic acid, alkyl phosphonic acid, glycerophosphonic acid, methylene diphosphonic acid, ethylene diphosphonic acid or the like; organic phosphoric esters such as optionally substituted phenyl phosphoric acid, naphthyl phorphoric acid, alkyl phosphoric acid, glycerophosphoric acid or the like; organic phosphinic acids such as optionally substituted phenyl phosphinic acid, naphthyl phosphinic acid, alkyl phosphinic acid, glycerophosphinic acid or the like; amino acids such as glycine, β-alanine or the like; amine hydrochlorides having a hydroxyl group such as triethanolamine hydrochloride or the like; and the like.

For the pore-sealing treatment, a treatment of constructing a film of a silane coupling agent having unsaturations may be carried out. As the silane coupling agent, mention may be made of, for example, N-3-(acryloxy-2-hydroxypropyl)-3-aminopropyltriethoxysilane, (3-acryloxypropyl)dimethylmethoxysilane, (3-acryloxypropyl)methyldimethoxysilane, (3-acryloxypropyl)trimethoxysilane, 3-(N-arylamino)propyltrimethoxysilane, aryldimethoxysilane, aryltriethoxysilane, aryltrimethoxysilane, 3-butenyltriethoxysilane, 2-(chloromethyl)aryltrimethoxysilane, methacrylamidopropyltriethoxysilane, N-(3-methacryloxy-2-hydroxypropyl)-3-aminopropyltriethoxysilane, (methacryloxymethyl)dimethylethoxysilane, methacryloxymethyltriethoxysilane, methacryloxymethyltrimethoxysilane, methacryloxypropyldimethylethoxysilane, methacryloxypropyldimethylmethoxysilane, methacryloxypropylmethyldiethoxysilane, methacryloxypropylmethyldimethoxysilane, methacryloxypropylmethyltriethoxysilane, methacryloxypropylmethyltrimethoxysilane, methacryloxypropyl tris(methoxyethoxy)silane, methoxydimethylvinylsilane, 1-methoxy-3-(trimethylsiloxy)butadiene, styrylethyltrimethoxysilane, 3-(N-styrylmethyl-2-aminoethylamino)-propyltrimethoxysilane hydrochloride, vinyldimethylethoxysilane, vinyldiphenylethoxysilane, vinylmethyldiethoxysilane, vinylmethyldimethoxysilane, O-(vinyloxyethyl)-N-(triethoxysilylpropyl)urethane, vinyltriethoxysilane, vinyltrimethoxysilane, vinyltri-t-butoxysilane, vinyltriisopropoxysilane, vinyltriphenoxysilane, vinyltris(2-methoxyethoxy)silane, and diarylaminopropylmethoxysilane. Among these, preferred are the silane coupling agents having a methacryloyl group and an acryloyl group whose unsaturation groups are fast-reactive.

In addition, mention may be made of the sol-gel coating treatment as described in JP-A No. 5-50779; the phosphonic acid coating treatment as described in JP-A No. 5-246171; the method of treatment by coating a material for backcoating as described in JP-A Nos. 6-234284, 6-191173 and 6-230563; the phosphonic acid treatment as described in JP-A No. 6-262872; the coating treatment as described in JP-A No. 6-297875; the anodic oxidation treatment method as described in JP-A No. 10-109480; the immersion treatment method as described in JP-A Nos. 2000-81704 and 2000-89466; or the like, and any of these methods may used.

After the formation of a hydrophilic film, if desired, hydrophilization treatment is carried out on the surface of the aluminum plate. Such hydrophilization treatment may be exemplified by the methods using alkali metal silicates as described in the specfications of U.S. Pat. Nos. 2,714,066, 3,181,461, 3,280,734 and 3,902,734. In these methods, the support is subjected to the immersion treatment or electrolysis treatment using an aqueous solution of sodium silicate or the like. In addition to these, there may be mentioned of the method of treating with potassium fluorozirconic acid as described in JP-B No. 36-22063, the method of treating with polyvinyl phosphonic acid s described in U.S. Pat. Nos. 3,276,868, 4,153,461 and 4,689,272, or the like.

In the case of using a support in which the surface hydrophilicity is insufficient, such as polyester film, as the support in the invention, it is preferable to make the surface hydrophilic by coating a hydrophilic layer thereon. As such hydrophilic layer, preferred are the hydrophilic layer formed by coating a coating liquid containing colloids of the oxide or hydroxide of at least one element selected from beryllium, magnesium, aluminum, silicon, titanium, boron, germanium, tin, zirconium, iron, vanadium, antimony and transition metals, as described in JP-A No. 2001-199175; the hydrophilic layer having an organic hydrophilic matrix obtained by crosslinking or pseudocrosslinking organic hydrophilic polymers, as described in JP-A No. 2002-79772; the hydrophilic layer having an inorganic hydrophilic matrix obtained by sol-gel transition which consists of hydrolysis and condensation of polyalkoxysilane, titanate, zirconate or aluminate; or the hydrophilic layer consisting of an inorganic thin film having a metal oxide-containing surface. Among these, the hydrophilic layer formed by coating a coating liquid containing the colloid of silicon oxide or silicon hydroxide is preferred.

Further, in the case of using polyester film or the like as the support in the invention, it is preferable to construct an antistatic layer on the hydrophilic layer side or the opposite side, or on both sides, of the support. If an antistatic layer is constructed between the support and the hydrophilic layer, it also contributes in improving the close adherence to the hydrophilic layer. As such antistatic layer, use can be made of the polymer layer or the like in which metal oxide microparticles or a matting agent is dispersed, as described in JP-A No. 2002-79772.

For the support, the average roughness at the central line is preferably 0.10 to 1.2 μm. In this range, good adherence to the photosensitive-thermosensitive layer, good resistance to printing and good anti-contamination property can be obtained.

Further, the color density of the support is preferably 0.15 to 0.65 as the value of the reflective density. In this range, good image formation property due to prevention of halation during light exposure of the image and good plate inspection property after development can be obtained.

[Backcoat Layer]

After implementation of the surface treatment or formation of an undercoat on the support, a backcoat can be constructed on the opposite side of the support, if desired.

As such backcoat, for example, the coating layer consisting of a metal oxide which is obtained by hydrolysis and polycondensation of an organic polymeric compound as described in JP-A No. 5-45885, or an organic metal compound or an inorganic metal compound as described in JP-A No. 6-35174 can be favorably mentioned. Inter alia, it is preferable to use an alkoxy compound of silicon such as Si(OCH₃)₄, Si(OC₂H₅)₄, Si(OC₃H₇)₄, Si(OC₄H₉)₄ or the like from the viewpoint of the availability of the raw materials at low costs.

[Undercoat Layer]

In the lithographic printing plate precursor of the invention, an undercoat layer can be constructed between the photosensitive-thermosensitive layer and the support, if desired. It is advantageous in achieving a high sensitization level because, as the undercoat layer functions as a heat-insulation layer, the heat generated by exposure to an infrared laser light can be utilized with good efficiency without being diffused into the support. Also, in the unexposed area, since the undercoat facilitates delamination of the photosensitive-thermosensitive layer from the support, the property of the on-board development is improved.

As the undercoat layer, specifically, the silane coupling agent having an ethylenically double-bonded reactive group which is capable of undergoing addition polymerization as described in JP-A No. 10-282679, the phosphorus compound having an ethylenically double-bonded reactive group as described in JP-A No. 2-304441, or the like can be mentioned favorably.

The coating amount (solids) of the undercoat layer is preferably 0.1 to 100 mg/m², and more preferably 1 to 30 mg/m².

[Protective Layer]

In the lithographic printing plate precursor of the invention, a protective layer can be constructed on the photosensitive-thermosensitive layer, if desired, under the purpose of prevention of the occurrence of damage, etc. in the photosensitive-thermosensitive layer, blocking of oxygen, and prevention of aberration upon exposure to a high illumination intensity laser.

According to the invention, exposure to light is typically carried out under the atmosphere, and the protective layer prevents incorporation into the photosensitive-thermosensitive layer, of any low molecular compound present in the atmosphere, which inhibits the image-forming reaction occurring in the photosensitive-thermosensitive layer upon light exposure, such as oxygen, basic substances or the like, and thus prevents inhibition of the image-forming reaction occurring in the atmosphere upon light exposure. Therefore, the properties required from the protective layer are preferably low permeability to a low molecular compound such as oxygen, good permeability to the light used in exposure, excellent adherence to the photosensitive-thermosensitive layer, and good removability during the process of the on-board development treatment after light exposure. Investigation on such protective layers having the above-mentioned properties is carried out more often than ever, and such protective layers are described in detail, for example, in U.S. Pat. No. 3,458,311 and JP-A No. 55-49729.

As the material used for the protective layer, examples may include water-soluble polymeric compounds having relatively high crystallinity. Specifically, mention may be made of water-soluble polymers such as polyvinyl alcohol, polyvinyl pyrrolidone, acidic celluloses, gelatin, gum Arabic, polyacrylic acid and the like.

When polyvinyl alcohol (PVA) among them is used as the main component, the best results can be obtained with respect to the fundamental properties such as oxygen blocking, removablity of the developed image or the like. Polyvinyl alcohol may be partially substituted by esters, ethers or acetals, or may partially contain other copolymerizable components, as long as the polymer contains the unsubstituted vinyl alcohol unit which provides the ability of blocking oxygen and water-solubility required in the protective layer.

Specific examples of polyvinyl alcohol may be preferably those with the degree of polymerization being in a range of 300 to 2400 and the degree of hydrolysis in a range of 71 to 100 mol %. Mention may be made specifically of, for example, PVA-105, PVA-110, PVA-117; PVA-117H, PVA-120, PVA-124, PVA-124H, PVA-CS, PVA-CST, PVA-HC, PVA-203, PVA-204, PVA-205, PVA-210, PVA-217, PVA-220, PVA-224, PVA-217EE, PVA-217E, PVA-220E, PVA-224E, PVA-405, PVA-420, PVA-613 and L-8.

The component of the protective layer (selection of PVA, use of additives, etc.), the coating amount or the like may be appropriately selected in consideration of the properties such as clouding, close adherence, resistance to damage or the like, in addition to the ability of blocking oxygen and removability of the developed image. In general, as the degree of hydrolysis of PVA increases (that is, as the content of the unsubstituted vinyl alcohol unit in the protective layer is higher), or as the film thickness increases, the ability of blocking oxygen also increases, and this is preferable in the aspect of sensitivity. Also, it is preferable not to have excessively high oxygen permeability, in order to prevent unnecessary polymerization reactions during production and storage, unnecessary clouding during exposure of the image, and thickening of the image lines. Thus, the oxygen permeability A is preferably such that 0.2≦A≦20 (cc/m²·day) at 25° C. and 1 atmosphere.

As other constituents of the protective layer, glycerin, dipropylene glycol may be added in an amount equivalent to several percent by mass with respect to the water-soluble polymeric compound, in order to impart flexibility, and anionic surfactants such as sodium alkyl sulfate, sodium alkyl sulfonate or the like; cationic surfactants such as alkylaminocarboxylic acid salts, alkylaminodicarboxylic acid salts or the like; and nonionic surfactants such as polyoxyethylene alkylphenyl ether or the like may be also added in an amount of several percent by mass with respect to the (co)polymer.

The film thickness of the protective layer is suitably 0.1 to 5 μm, and particularly preferably 0.2 to 2 μm.

In addition, the close adherence to the image area, resistance to damage and the like are also very important in terms of the handlability of the lithographic printing plate precursor. That is, for the protective layer contains a water-soluble polymeric compound, when the hydrophilic protective layer is laminated on the photosensitive-thermosensitive layer, the latter being oleophilic, delamination of the protective layer due to insufficient adhesive force is susceptible to occur, and there is a risk of suffering from defects such as poor film curing and the like, which in turn causes suppression of polymerization by oxygen at the delaminated area.

In this regard, there have been a variety of suggestions to improve adherence between the photosensitive-thermosensitive layer and the protective layer. For example, it is described in JP-A No. 49-70702 and GB-A No. 1303578 that sufficient adherence can be achieved by mixing in a hydrophilic polymer mainly consisting of polyvinyl alcohol, an acrylic emulsion, a water-insoluble vinyl pyrrolidone-vinyl acetate copolymer or the like in a portion of 20 to 60% by mass and laminating the mixture on the photosensitive-thermosensitive layer. According to the invention, all of these known techniques can be used. For the coating method of the protective layer, for example, U.S. Pat. No. 3,458,311 and JP-A No. 55-49729 describe the methods in detail.

Moreover, other functions can be also imparted to the protective layer. For example, the aptitude to safelight can be improved without lowering of the sensitivity, by adding a coloring agent (for example, a water-soluble dye) which is excellent in the permeability to the infrared ray used in light exposure, and which can absorb efficiently the light of a wavelength other than the foregoing.

[Exposure to Light]

In the lithographic printing method of using the lithographic printing plate precursor of the invention, the lithographic printing plate precursor described previously is exposed to an infrared laser in image pattern.

The infrared laser used in the invention is not particularly limited, but the solid laser and semiconductor laser which emits an infrared ray with a wavelength of 760 to 1200 nm can be preferably mentioned. The output of the infrared laser is preferably 100 mW or more. Further, it is preferable to use a multibeam laser device to shorten the length of exposure.

The length of exposure per pixel is preferably within 20 μsec. Also, the quantity of the irradiation energy is preferably 10 to 300 mJ/cm².

[Method of Printing]

The printing method of using the lithographic printing plate precursor of the invention comprises exposing to an infrared laser in image pattern and subsequently printing by supplying an oily ink and an aqueous component, without going through any development step, as described in the above.

Specifically, a method of printing by exposing the lithographic printing plate precursor to an infrared laser and then mounting the plate on the printing press for printing, without subjecting the plate to any development step; a method of printing by mounting the lithographic printing plate precursor on the printing press and then exposing the precursor to an infrared laser on the printing press, without subjecting the plate to any development step, or the like can be achieved.

For example, in an embodiment of the negative, on-board development type lithographic printing plate precursor, when the lithographic printing plate precursor is exposed to an infrared laser in image pattern, and then printing is carried out by supplying an aqueous component and an oily ink without going through a development step such as the wet development step, at the exposed area of the photosensitive-thermosensitive layer, the portion of the photosensitive-thermosensitive layer cured by light exposure forms an oily ink-receiving area having an oleophilic surface. On the other hand, at the unexposed area, the uncured portion of the photosensitive-thermosensitive layer is removed by dissolution or dispersion with the supplied aqueous component and/or oily ink, and a hydrophilic surface is exposed at the portion.

As a result, the aqueous component is adhered on the exposed hydrophilic surface, and the oily ink is deposited on the light-exposed area of the photosensitive-thermosensitive layer, thereby printing being commenced. Here, the first to be supplied onto the plate surface may be either the aqueous component or the oily ink; however, from the perspective of preventing contamination of the aqueous component by the unexposed portion of the photosensitive-thermosensitive layer, the oily ink is preferably supplied first. For the aqueous component and the oily ink, conventional fountain solutions and printing inks for lithographic printing are used.

In this manner, the lithographic printing plate precursor is developed on-board on the off-set printing press and is used as such in multiple printing.

### EXAMPLES

Now, the invention will be explained in detail by way of Examples, which are not intended to limit the invention in any way.

### Example 1

<Preparation of Aluminum Support>

In order to remove any oil for rolling from the surface of a 0.3-mm thick aluminum plate (material JIS1050), degreasing was carried out using a 10 mass % aqueous solution of sodium aluminate at 50° C. for 30 seconds, and then the surface of the aluminum plate was sandblasted using three bundle-type nylon brushes with a hair diameter of 0.3 mm and an aqueous suspension (specific gravity 1.1 g/cm³) of pumice with a median size of 25 μm, and washed thoroughly with water. This plate was etched by immersing it in a 25 mass % aqueous solution of sodium hydroxide at 45° C. for 9 seconds, washed with water, and then immersed again in a 20 mass % nitric acid at 60° C. for 20 seconds, followed by washing with water. Here, the etched amount of the sandblasted plate surface was about 3 g/m².

Next, electrochemical surface-roughening was carried out continuously using an alternating current of 60 Hz. Here, the electrolytic solution was a 1 mass % aqueous solution of nitric acid (containing 0.5% by mass of aluminum ions), and the solution temperature was 50° C. Using an alternating current of the trapezoid rectangular wave type with a waveform such as that the time taken by the current to reach from 0 to the peak value, TP, was 0.8 msec and the duty ratio was 1:1, electrochemical surface roughening treatment was carried out with a carbon electrode as the counter electrode. As an auxiliary anode, ferrite was used. The current density was 30 A/dm² as the current peak value, and 5% of the current flowing from the power supply was splitted into the auxiliary anode. The quantity of electricity in the nitric acid electrolysis was 175 C/dm² as the quantity of electricity when the anode was the aluminum plate. Subsequently, water rinsing by spraying was carried out.

Next, in an electrolytic solution of a 0.5 mass % aqueous solution of hydrochloric acid (containing 0.5 mass % of aluminum ions) at the solution temperature of 50° C., and under the condition of the quantity of electricity 50 C/dm² of when the anode is the aluminum plate, the electrochemical surface roughening treatment was carried out in the same manner as in the above-mentioned nitiric acid electrolysis, and then water rinsing by spraying was carried out. This plate was constructed thereon with 2.5 g/m² of D.C.-anodic oxidation film using a 15 mass % sulfuric acid (containing 0.5% by mass of aluminum ions) at a current density of 15 A/dm², subsequently rinsed with water, dried and treated with a 2.5 mass % aqueous solution of sodium silicate at 30° C. for 10 seconds. The average roughness at the central line (Ra) at the surface of this support was measured using a needle with a diameter of 2 μm, which was 0.51 μm.

<Formation of the Undercoat>

A coating liquid for undercoat (1) having the following composition was bar coated on the above support, and then the assembly was dried open at 80° C. for 20 seconds to form an undercoat layer with a dried coating amount of 0.005 g/m².

Coating solution for undercoat (1)

| | |
|---|---|
| Water | 10 g |
| Methanol | 90 g |
| the following Polymer (1) | 0.09 g |

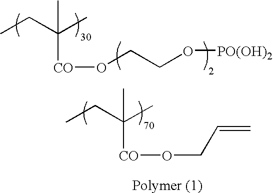

<Preparation of Lithographic Printing Plate Precursor>

A coating liquid for photosensitive-thermosensitive layer (1) having the following composition was bar coated on the above undercoat layer and then was dried open at 70° C. for 60 seconds to form a photosensitive-thermosensitive layer of a dried coating amount of 1.0 g/m². Thus, a lithographic printing plate precursor (1) was obtained.

Coating solution for photosensitive-thermosensitive layer (1)

| | |
|---|---|
| Water | 50 g |
| Propylene glycol monomethyl ether | 50 g |
| the following microcapsules (1) | 6 g |
| (in terms of the solids) | |
| the following microcapsules (2) | 2.5 g |
| (in terms of the solids) | |
| the following polymerization initiator (1) | 1 g |
| Isocyanuric acid EO-modified triacrylate | 0.5 g |
| (product by Toagosei Co., Ltd.; NK Ester M-315) | |
| the following fluorine-based surfactant (1) | 0.1 g |

Polymerization initiator (1)

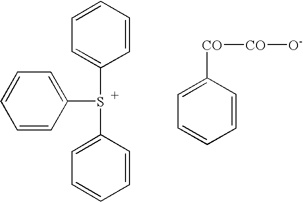

Fluorine-based surfactant (1)

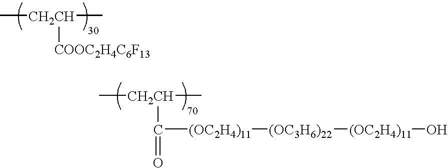

(Synthesis of Microcapsules (1))

As the oil-phase components, 8.7 g of an adduct of trimethylolpropane and xylene diisocyanate (product by Sankyo-Takeda Chemical Co., Ltd.; Takenate D-110N), 1 g of 2-methacryloyloxyethyl isocyanate (product by Showa Denko K.K.; Karenz MOI), 5.5 g of isocyanuric acid EO-modified triacrylate (product by Taogosei Co., Ltd.; NK Ester M-315), 0.5 g of the following infrared absorbent (1), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of polyvinyl alcohol (product by Kuraray Co., Ltd.; PVA-205) was prepared. The oil-phase components and the aqueous-phase component were mixed and emulsified by a homogenizer at 12,000 rpm for 10 minutes. To thus obtained emulsion, 25 g of distilled water was added, and the mixture was stirred for 30 minutes at room temperature and then for another 3 hours at 40° C. Thus obtained microcapsule solution was diluted with distilled water such that the solid concentration was 20% by mass. The average particle size was 0.3 μm.

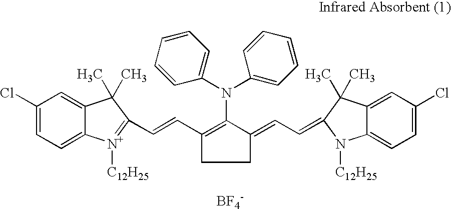

(Synthesis of Microcapsules (2))

As the oil-phase components, 10 g of an adduct of trimethylolpropane and xylene diisocyanate (product by Sankyo-Takeda Chemical Co., Ltd.; Takenate D-110N), 5 g of Bindschedler's Green (product by Tokyo Chemical Industry Co., Ltd.; see below), 0.5 g of the following infrared absorbent (2), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 0.38 g of tetraethylene pentaamine and 25 g of distilled water were added, and the mixture was stirred for 30 minutes at room temperature and then for another 3 hours at 65° C. Thus obtained microcapsule solution was diluted with distilled water such that the solid concentration was 20% by mass. The average particle size was 0.3 μm.

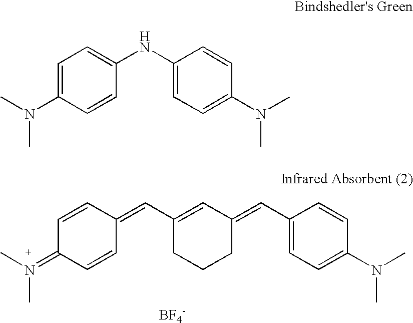

### Example 2

A lithographic printing plate precursor was obtained in the same manner as in Example 1, except that a coating liquid for photosensitive-thermosensitive layer (2) of the following composition was bar coated and then dried open at 80° C. for 60 seconds to form a photosensitive-thermosensitive layer of a dried coating amount of 1.0 g/m².

Coating solution for photosensitive-thermosensitive solution (2)

| | |
|---|---|
| the following infrared absorbent (3) | 0.3 g |
| the following polymerization initiator (1) | 0.9 g |
| the following binder polymer (1) | 2.5 g |
| Polymerizable compound | 5.4 g |
| Pentaerythritol triacrylate (product by Nippon | |
| Kayaku Co., Ltd.; SR444) | |
| the following Microcapsules (2) | 2.5 g |
| (in terms of the solids) | |
| the above fluorine-based surfactant (1) | 0.1 g |
| Methanol | 10 g |
| Water | 35 g |
| Propylene glycol monomethyl ether | 50 g |

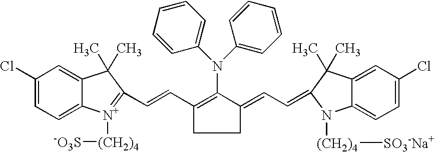

Infrared Absorbent (3)

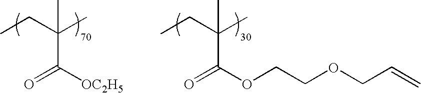

Binder Polymer (1)

### Example 3

A lithographic printing plate precursor was obtained in the same manner as in Example 1, except that a coating liquid for photosensitive-thermosensitive layer (3) of the following composition was bar coated and then dried open at 80° C. for 60 seconds to form a photosensitive-thermosensitive layer of a dried coating amount of 1.0 g/m².

Coating solution for photosensitive-thermosensitive layer (3)

| | | |
|---|---|---|
| the above infrared absorbent (2) | 0.3 | g |
| the above polymerization initiator (1) | 0.9 | g |
| the above binder polymer (1) | 2.5 | g |
| Polymerizable compound | 5.4 | g |
| Pentaerythritol triacrylate (product by Nippon | | |
| Kayaku Co., Ltd.; SR444) | | |
| the above microcapsules (2) | 2.5 | g |
| (in terms of the solids) | | |
| the following microcapsules (3) | 2.5 | g |
| (in terms of the solids) | | |
| the above fluorine-based surfactant (1) | 0.1 | g |
| Methanol | 10 | g |
| Water | 35 | g |
| Propylene glycol monomethyl ether | 50 | g |

(Synthesis of Microcapsules (3))

As the oil-phase components, 8.7 g of an adduct of trimethylolpropane and xylene diisocyanate (product by Sankyo-Takeda Chemical Co., Ltd.; Takenate D-110N), 1 g of 2-methacryloyloxyethyl isocyanate (product by Showa Denko K.K.; Karenz MOI), 6 g of pentaerythritol triacrylate (product by Nippon Kayaku Co., Ltd.; SR444), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 25 g of distilled water was added, and the mixture was stirred for 30 minutes at room temperature and then for another 3 hours at 40° C. Thus obtained microcapsule solution was diluted with distilled water such that the solid concentration was 20% by mass. The average particle size was 0.3 μm.

### Example 4

A lithographic printing plate precursor was obtained in the same manner as in Example 3, except that the following coating liquid for protective layer (1) was bar coated on the photosensitive-thermosensitive layer of Example 3 and then dried open at 100° C. for 60 seconds to form a protective layer of a dried coating amount of 0.5 g/m².

Coating solution for protective layer (1)

| | |
|---|---|
| Polyvinyl alcohol | 1.0 g |
| (degree of saponification 98.5 mol %) | |
| (product by Kuraray Co., Ltd.; PVA105) | |
| Polyoxyethylene lauryl ether | 0.01 g |
| (product by Nihon Emulsion Co., Ltd.; Emalex 710) | |
| Water | 19.0 g |

### Example 5

A lithographic printing plate precursor was obtained in the same manner as in Example 1, except that the microcapsules (2) in the coating liquid for photosensitive-thermosensitive layer (1) of Example 1 were all replaced by the following microcapsules (4).

(Synthesis of Microcapsules (4))

As the oil-phase components, 10 g of an adduct of trimethylolpropane and xylene diisocyanate (product by Sankyo-Takeda Chemical Co., Ltd.; Takenate D-110N), 5 g of Bindschedler's Green (product by Tokyo Chemical Industry Co., Ltd), 0.5 g of the following infrared absorbent (V), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 0.38 g of tetraethylene pentaamine and 25 g of distilled water were added, and the mixture was stirred for 30 minutes at room temperature and then for another 3 hours at 65° C. Thus obtained microcapsule solution was diluted with distilled water such that the solid concentration was 20% by mass. The average particle size was 0.3 μm.

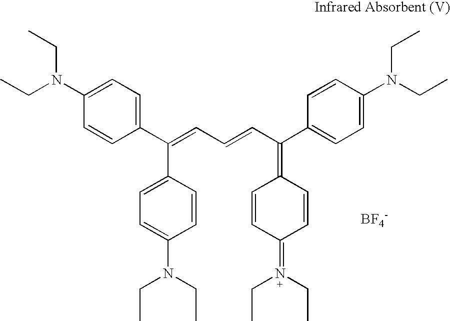

### Example 6

A lithographic printing plate precursor was obtained in the same manner as in Example 1, except that the microcapsules (2) in the coating liquid for photosensitive-thermosensitive layer (1) of Example 1 were all replaced by the following microcapsules (X).

(Synthesis of Microcapsules (X))

As the oil-phase components, 10 g of an adduct of trimethylolpropane and xylene diisocyanate (product by Sankyo-Takeda Chemical Co., Ltd.; Takenate D-110N), 5 g of the following compound (Z), 0.5 g of the following infrared absorbent (A), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 0.38 g of tetraethylene pentaamine and 25 g of distilled water were added, and the mixture was stirred for 30 minutes at room temperature and then for another 3 hours at 65° C. Thus obtained microcapsule solution was diluted with distilled water such that the solid concentration was 20% by mass. The average particle size was 0.3 μm.

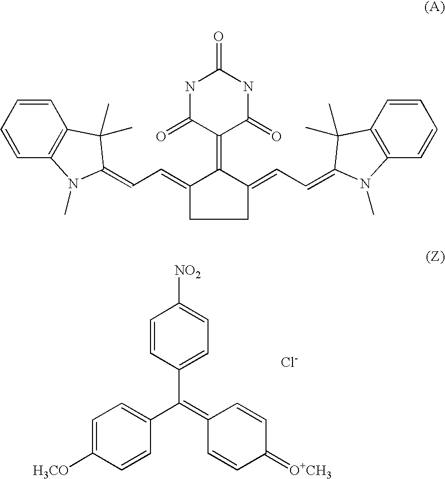

### Example 7

A lithographic printing plate precursor was obtained in the same manner as in Example 1, except that the microcapsules (2) in the coating liquid for photosensitive-thermosensitive layer (1) of Example 1 were all replaced by the following microcapsules (Y).

(Synthesis of Microcapsules (Y))

As the oil-phase components, 10 g of an adduct of trimethylolpropane and xylene diisocyanate (product by Sankyo-Takeda Chemical Co., Ltd.; Takenate D-110N), 5 g of the above compound (Z), 0.5 g of the following infrared absorbent (B), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 0.38 g of tetraethylene pentaamine and 25 g of distilled water were added, and the mixture was stirred for 30 minutes at room temperature and then for another 3 hours at 65° C. Thus obtained microcapsule solution was diluted with distilled water such that the solid concentration was 20% by mass. The average particle size was 0.3 μm.

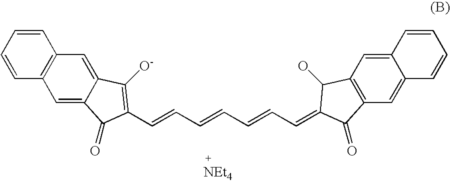

### Comparative Example 1

A lithographic printing plate precursor was obtained in the same manner as in Example 1, except that the microcapsules (2) in the coating liquid for photosensitive-thermosensitive layer (1) of Example 1 were all replaced by the following microcapsules (5).

(Synthesis of Microcapsules (5))

As the oil-phase components; 10 g of an adduct of trimethylolpropane and xylene diisocyanate (product by Sankyo-Takeda Chemical Co., Ltd.; Takenate D-110N), 0.5 g of the above infrared absorbent (2), and 0.1 g of sodium dodecylbenzene sulfonate (product by Takemoto Oil & Fat Co., Ltd.; Pionin A-41C) were dissolved in 17 g of ethyl acetate. As the aqueous-phase component, 40 g of a 4 mass % aqueous solution of PVA-205 was prepared. The oil-phase components and the aqueous-phase component were mixed and emulsified by a homogenizer at 12,000 rpm for 10 minutes. To thus obtained emulsion, 0.38 g of tetraethylene pentaamine and 25 g of distilled water were added, and the mixture was stirred for 30 minutes at room temperature and then for another 3 hours at 65° C. Thus obtained microcapsule solution was diluted with distilled water such that the solid concentration was 20% by mass. The average particle size was 0.3 μm.

### Comparative Example 2

A lithographic printing plate precursor was obtained in the same manner as in Example 2, except that the microcapsules (2) in the coating liquid for photosensitive-thermosensitive layer (2) of Example 2 were all replaced by the following microcapsules (5).

### Comparative Example 3

A lithographic printing plate precursor was obtained in the same manner as in Example 3, except that the microcapsules (2) in the coating liquid for photosensitive-thermosensitive layer (3) of Example 3 were all replaced by the following microcapsules (5).

### Comparative Example 4

On the photosensitive-thermosensitive layer of the lithographic printing plate precursor obtained in Comparative Example 3, a protective layer was constructed in the same manner as in Example 4 to obtain a lithographic printing plate precursor having a protective layer.

### Comparative Example 5

A lithographic printing plate precursor was obtained in the same manner as in Comparative Example 1, using the microcapsules modified from the microcapsules (5) of Comparative Example 1 by replacing the infrared absorbent (2) with the above-mentioned infrared absorbent (V).

### Comparative Example 6

A lithographic printing plate precursor was obtained in the same manner as in Comparative Example 1, using the microcapsules modified from the microcapsules (5) of Comparative Example 1 by replacing the infrared absorbent (2) with the above-mentioned infrared absorbent (A).

### Comparative Example 7

A lithographic printing plate precursor was obtained in the same manner as in Comparative Example 1, using the microcapsules modified from the microcapsules (5) of Comparative Example 1 by replacing the infrared absorbent (2) with the above-mentioned infrared absorbent (B).

[Evaluation of Lithographic Printing Plate Precursor]

1. Evaluation of Burned Images

The obtained lithographic printing plate precursor was exposed to light using Trendsetter 3244VX (product by Creo, Inc.) loaded with a water-cooled 40-W infrared semiconductor laser, in the quantities of plate surface energy as indicated in Table 1, at a resolution of 2400 dpi.

In order to evaluate the burned images, the L* values at the exposed area and the unexposed area were measured using a colorimeter (Spectrophotometric calorimeter CR-221, product by Minolta), and the absolute value of the difference between the two values was taken as the difference in brightness (ΔL).

The results were indicated in Table 1 as an index based on the ΔL value of Example 1 (100). This ΔL index is such that as the number is larger, the visibility increases, thus being preferable.

2. On-Board Development and Evaluation of Printing

The obtained exposed plate precursor was mounted on the cylinder of the printing press SOR-M, a product by Heidelberg Co., Ltd., without going through the step of development. The supply of fountain solution and ink was made using a fountain solution (EU-3 (an etching solution by Fuji Photo Film, Co., Ltd.)/water/isopropyl alcohol=1/89/10 (volume ratio)) and TRANS-G(N) black ink (product of Dainippon Ink and Chemicals, Inc.), and printing was performed at a printing speed of 6000 sheets per hour.

As a result, with any of the lithographic printing plate precursor, good capability of the on-board development was obtained, and there were obtained printing products up to 100 sheets having no contamination in the non-image area.

Further, printing of 5000 sheets was carried out thereafter, and with any of the lithographic printing plate precursor, there were obtained good printing products showing no reduction in the ink concentration in the image area and having no contamination in the non-image area.

TABLE 1
Results of the difference in brightness ΔL

| | Energy of exposure | Difference in |
|---|---|---|
| | (mJ/cm²) | brightness, ΔL |
| Example 1 | 100 | 100 |
| Example 2 | 100 | 95 |
| Example 3 | 100 | 115 |
| Example 4 | 100 | 110 |
| Example 5 | 100 | 125 |
| Example 6 | 100 | 85 |
| Example 7 | 100 | 80 |
| Comparative Example 1 | 100 | 10 |
| Comparative Example 2 | 100 | 5 |
| Comparative Example 3 | 100 | 5 |
| Comparative Example 4 | 100 | 10 |
| Comparative Example 5 | 100 | 10 |
| Comparative Example 6 | 100 | 10 |
| Comparative Example 7 | 100 | 10 |

As shown in the results above, the lithographic printing plate precursor of the invention shows high difference in brightness and excellent visibility.

According to the invention, it is possible to provide a lithographic printing plate precursor of the on-board development type or of the non-treatment (non-development) type, which enables burning of an image with high visibility that facilitates identification of the plate after the step of exposure in image pattern with an infrared laser. Further, the invention can provide a lithographic printing method of using such lithographic printing plate precursor of the on-board development type.

The entire disclosure of each and every foreign patent application from which the benefit of foreign priority has been claimed in the present application is incorporated herein by reference, as if fully set forth.

1. A lithographic printing plate precursor comprising:
a support; and
a photosensitive-thermosensitive layer that allows image recording by exposure to an infrared laser light,
wherein the photosensitive-thermosensitive layer comprises (1) an infrared absorbent and (2) a compound which undergoes color change upon oxidation or reduction.

2. The lithographic printing plate precursor according to claim 1,
wherein the infrared absorbent (1) is at least one selected from cyanine colorants, melocyanine colorants and oxonol colorants, and
wherein the compound (2) which undergoes color change upon oxidation is at least one selected from leuco triarylmethane compounds, leuco diarylmethane compounds, leuco xanthene compounds, leuco thioxanthene compounds and arylamine compounds.

3. The lithographic printing plate precursor according to claim 1,
wherein the infrared absorbent (1) is at least one selected from cyanine colorants, pyrylium colorants and thiopyrylium colorants, and
wherein the compound (2) which undergoes color change upon reduction is at least one selected from diarylmethane colorants, triarylmethane colorants, thiazine colorants, xanthene colorants and azomethine colorants.

4. The lithographic printing plate precursor according to claim 1, wherein the photosensitive-thermosensitive layer further comprises (3) a radical-polymerizable compound and a radical polymerization initiator.

5. The lithographic printing plate precursor according to claim 4, wherein at least one of: the infrared absorbent (1); the compound (2); and the radical-polymerizable compound and the radical polymerization initiator (3) is encapsulated in microcapsules.

6. A platemaking method for a lithographic printing plate precursor, comprising:
mounting the lithographic printing plate precursor according to claim 1, on a printing press;
imagewise exposing the lithographic printing plate precursor with an infrared laser; and
supplying printing ink and fountain solution onto the lithographic printing plate precursor to remove an infrared laser light-unexposed area of the photosensitive-thermosensitive layer.

7. The platemaking method for a lithographic printing plate precursor, according to claim 6;
wherein the mounting is performed before the imagewise exposing.

8. The platemaking method for a lithographic printing plate precursor, according to claim 6;
wherein the mounting is performed after the imagewise exposing.

9. A lithographic printing method comprising:
mounting the lithographic printing plate precursor according to claim 1, on a printing press;
imagewise exposing the lithographic printing plate precursor with an infrared laser;
supplying printing ink and fountain solution onto the lithographic printing plate precursor to remove an infrared laser light-unexposed area of the photosensitive-thermosensitive layer; and
printing.

10. The lithographic printing method according to claim 9;
wherein the mounting is performed before the imagewise exposing.

11. The lithographic printing method according to claim 9;
wherein the mounting is performed after the imagewise exposing.
